(19) United States
(12) Patent Application Publication
(10) Pub. No.: US 2014/0139293 A1
(43) Pub. Date: May 22, 2014

(54) INTEGRATED REFERENCE FREQUENCY GENERATOR

(71) Applicant: CYMATICS LABORATORIES CORP., Pittsburgh, PA (US)

(72) Inventors: Anthony L. Tsangaropoulos, San Carlos, CA (US); David Francois Guillou, Pittsburgh, PA (US)

(73) Assignee: CYMATICS LABORATORIES CORP., Pittsburgh, PA (US)

(21) Appl. No.: 13/680,807

(22) Filed: Nov. 19, 2012

(51) Int. Cl. H03B 28/00

(52) U.S. Cl. CPC H03B 28/00
USPC 331/48

(57) ABSTRACT

An integrated circuit device for generating an output frequency includes a master oscillator and a slave oscillator formed on an integrated circuit substrate. The master oscillator utilizes a bulk acoustic wave resonator that provides a reference frequency source to the device. The frequency of the slave oscillator is periodically adjusted with respect to the reference frequency source and provided as an output. The master oscillator is periodically enabled to adjust the slave oscillator. Additional automatic temperature compensation is enabled as necessary.

### BACKGROUND

Clock or timing signals are employed in electronic devices for many different purposes, including but not limited to clocking a microprocessor, a microcontroller, a central processing unit (CPU), a graphics processing unit (GPU), a digital signal processor (DSP), a digital logic state machine, etc., or clocking an analog-to-digital converter (ADC), a digital-to-analog converter (DAC), a sampled-data filter, a discrete-time analog signal processor, etc. The frequency of these timing signals ranges from the tens of kHz to hundreds of MHz. The power consumption requirement is in the range of one microwatt to ten milliwatts, while the typical frequency accuracy is in the range of ±10 to ±100 ppm.

Typical implementations of low-power frequency generators are classified as either harmonic oscillators or relaxation oscillators. The oscillation frequency of relaxation oscillators is set by an energy storage element (e.g. an inductor or a capacitor) and a resistor. A defining property of relaxation oscillators is that they produce waveforms with discontinuous first derivatives (i.e. pulse trains). The oscillation frequency of harmonic oscillators is set by a resonant tank, e.g. composed of two energy reservoirs, an inductive element and a capacitive element, two capacitive elements or two inductive elements. Quartz crystal oscillators are considered harmonic oscillators since a piezoelectric resonator is a resonant tank.

Quartz resonators have been the preferred resonator technology for the past 50 years for oscillators that require high accuracy and stability. Depending on their cut (i.e. crystal orientation), quartz resonators can operate on a fundamental frequency mode of oscillation, or on a harmonic or overtone mode. In addition, different quartz resonator cuts entail different stability characteristics. For example, the X-cut produces a less stable resonator than the popular AT-cut. Fundamental-mode oscillators, operating on the fundamental resonance mode of the quartz crystal, generate a fixed frequency in the range of approximately 1 MHz to approximately 50 MHz and achieve a long-term frequency accuracy better than 100 ppm. Of the various harmonic oscillators, the ones using piezoelectric resonators are known to have the best phase noise/jitter performance and frequency stability. However, such oscillators consume typically 1 mW to 5 mW (not including the power required to drive the load). Overtone-mode oscillators can generate output frequencies in the range of approximately 50 MHz to approximately 300 MHz, but also consume at least several mW.

One significant disadvantage of quartz resonators is their comparatively large size and their requirement of an expensive hermetic package (typically a leadless ceramic chip carrier or LCCC package, with a glass or metal seal). The size of such a quartz oscillator ranges from 35 mm², which is too large for today's portable and many other applications, down to 1.9 mm². But, as the size shrinks, cost rises and performance (such as frequency accuracy and jitter) degrades. In addition, quartz crystal resonators raise board layout considerations since they have to be placed next to the oscillator IC and also be shielded from noise and electromagnetic interference (EMI).

On miniaturized handheld devices, all large components (such as the above-described quartz resonators) need to be eliminated. However, the quartz resonators are not easily integrated with other components in a single package due to their size, their special hermetic packaging requirements and the performance issues described above. Complete chip integration is prohibitive since their size and process of manufacture are incompatible with semiconductor die fabrication.

Relaxation oscillators can achieve much lower power consumption than quartz oscillators. However, as frequency-determining devices, integrated inductors, capacitors and resistors offer very poor manufacturing accuracy and stability over temperature, which results in lower frequency stability, compared to piezoelectric resonators. Furthermore, parasitics can be significant especially for operational frequencies above approximately 500 MHz. Also, the use of resistors entails degraded phase noise and jitter because of their inherently smaller quality factor (Q). Thus, generally, relaxation oscillators tend to not be as stable as harmonic oscillators. Harmonic oscillators that do not use resistors as frequency determining elements can be more stable and feature lower jitter but require constant and stable biasing which in turn increases their power consumption. Also harmonic oscillator resonant tanks made out of inductors and capacitors require large silicon areas for operational frequencies lower than approximately 100 MHz, and this area requirement grows significantly as the resonance frequency is lowered.

To address the deficiencies of the above-described stand-alone oscillators, several approaches have been used to extend the higher frequency stability of a certain high quartz crystal oscillator to a lower stability oscillator operating at lower power. A high-accuracy oscillator (e.g. a quartz reference oscillator) periodically corrects the frequency of a low-power, low-accuracy oscillator. The reference oscillator is typically a quartz oscillator. Since the frequency-corrected oscillator consumes a fraction of the power of the reference oscillator, significant power savings can be obtained in applications such as battery-powered horology.

A typical frequency correction for these devices utilizes a means of comparing the phase or frequency of the reference oscillator with the phase or frequency of the low-power oscillator, and either: 1) directly correcting the frequency of the low-power oscillator, or 2) correcting the output frequency by changing the division ratio of the output frequency divider.

Although the periodic frequency correction approach described above is utilized in applications such as Real-Time-Clocking (RTC) frequency generators, typically operating at 32.768 kHz, the benefits of this method diminish as the output frequency increases into the MHz range or higher. Since a quartz oscillator must be used to achieve high stability, the periodic frequency correction approach offers no cost or performance advantages. In addition, the usable frequency of typical reference AT-cut quartz oscillators is limited to less than approximately 50 MHz for a fundamental mode and approximately 150 MHz for a 3rd overtone, which introduces limitations in the power consumption, frequency division and correction mechanisms.

Furthermore, the required startup and stabilization time of MHz-range quartz oscillators is approximately in the millisecond range, which greatly increases the energy expended during the calibration process. It is thus desired to reduce this power and time as much as possible.

An additional shortcoming of the existing approaches is that the correction range is limited by the reference oscillator frequency. If several outputs are desired, output frequencies will be concentrated around a particular frequency value as allowed by minimum divider ranges and careful frequency planning.

Accordingly, new frequency generator circuit architectures are required that are compact and integratable, that can consume very low power, that provide frequency-stable operation, that are flexible, and that can be manufactured at a low cost. In addition, it is desired to integrate a high performance resonator on-chip with other circuits including a lower frequency oscillator operating at lower power.

### SUMMARY

Embodiments of the disclosure can be implemented in numerous ways, including as an apparatus and/or a system.

A detailed description of one or more embodiments of the invention is provided below along with accompanying figures that illustrate the principles of the invention. The invention is described in connection with such embodiments, but the invention is not limited to any embodiment. The scope of the invention is limited only by the claims, and the invention encompasses numerous alternatives, modifications, and equivalents. Numerous specific details are set forth in the following description in order to provide a thorough understanding of the invention. These details are provided for the purpose of example, and the invention may be practiced according to the claims without some or all of these specific details. For the purpose of clarity, technical material that is known in the technical fields related to the invention has not been described in detail so that the invention is not unnecessarily obscured.

An oscillator that comprises an integrated Bulk Acoustic Wave (BAW) resonator operating approximately in the 500 MHz-to-5 GHz range, combined with a fractional frequency divider or a direct digital synthesizer (DDS), one or more low-power oscillators, and logic circuitry to determine and apply frequency adjustment to the low-power oscillators is described herein. The adjustment can be done either via a fractional frequency divider or a direct digital synthesizer, or directly into frequency tuning elements of the low-power oscillators. Besides the low power operation, the elimination of the external quartz crystal offers significant advantages over existing solutions.

An integrated oscillator using an in-package BAW resonator, requiring no external quartz crystal, is used as a master frequency reference (or master oscillator, or reference oscillator). The oscillation frequency can be in the range of approximately 500 MHz to approximately 5000 MHz. The output of the master oscillator is processed by a direct digital synthesizer (DDS) which can include a fractional frequency divider and a phase interpolator, and delivers a reference frequency to a frequency/phase comparator, which compares it with a signal whose frequency is derived from the slave oscillator. The DDS in combination with BAW oscillators, such as demonstrated in U.S. Pat. No. 8,242,850, can be utilized. U.S. Pat. No. 8,242,850 is incorporated by reference herein. The frequency adjustment can be directly applied to the slave oscillator or indirectly applied to a secondary DDS. In one aspect, an integrated circuit device for generating an output signal includes a master oscillator circuit, a direct digital synthesizer circuit, and a slave oscillator circuit formed over an integrated circuit substrate. A reference frequency signal is generated from the master oscillator circuit by the direct digital synthesizer circuit. The output signal of the integrated circuit device is generated from the slave oscillator circuit. A frequency of the output signal of the integrated circuit device is intermittently adjusted with respect to a frequency of the reference frequency signal. The master oscillator circuit is intermittently enabled to adjust the frequency of the slave oscillator circuit output signal. The master oscillator circuit comprises a bulk acoustic wave resonator.

In one aspect, an integrated circuit device for generating an output signal includes a master oscillator circuit and a slave oscillator circuit. The integrated circuit device is formed over an integrated circuit substrate. A reference frequency signal is generated from the master oscillator circuit. The output signal of the integrated circuit device is generated from the slave oscillator circuit. The master oscillator circuit is intermittently enabled. As used herein, “intermittently enabled,” includes both periodically and non-periodically enabled. A frequency of the output signal of the integrated circuit device is intermittently adjusted with respect to a frequency of the reference frequency signal. As used herein, “intermittently adjusted” includes both periodically adjusted and non-periodically adjusted. The master oscillator circuit includes a bulk acoustic wave resonator.

### BRIEF DESCRIPTION OF THE DRAWINGS

The foregoing and other objects and advantages of the invention will be appreciated more fully from the following further description thereof, with reference to the accompanying drawings.

FIGS. 1A-1F illustrate various Chip-Scale-Packaging options employed with aspects of the present invention.

FIGS. 2A-2B illustrate a Multi-Chip Module packaging option employed with aspects of the present invention.

FIG. 3 shows a functional block diagram of an embodiment of an integrated reference frequency generator in accordance with aspects of the present invention.

FIG. 4 shows a functional block diagram of an embodiment of an integrated reference frequency generator in accordance with aspects of the present invention.

FIGS. 5A-5D show timing diagrams of frequency and current responses of embodiments employed with aspects of the present invention.

FIG. 6 shows a functional block diagram of an embodiment of an integrated reference frequency generator in accordance with aspects of the present invention.

FIG. 7 shows a functional block diagram of an embodiment of an integrated reference frequency generator in accordance with aspects of this invention.

FIG. 8 shows a functional block diagram of an embodiment of an integrated reference frequency generator in accordance with aspects of this invention.

FIG. 9 shows a functional block diagram of an embodiment of an integrated reference frequency generator in accordance with aspects of the invention.

FIG. 10 shows a functional block diagram of an embodiment of an integrated reference frequency generator in accordance with aspects of the invention.

FIGS. 11A-B show two functional block diagrams of embodiments of an integrated reference frequency generator in accordance with aspects of the invention.

FIG. 12 shows a functional block diagram of an embodiment of an integrated reference frequency generator in accordance with aspects of this invention.

FIG. 13 shows a functional block diagram of an embodiment of an integrated reference frequency generator in accordance with aspects of the invention.

FIG. 14 shows a functional block diagram of an embodiment of an integrated reference frequency generator in accordance with aspects of the invention.

FIG. 15 shows a functional block diagram of an embodiment of an integrated reference frequency generator in accordance with aspects of this invention.

### DETAILED DESCRIPTION

The present invention is described in terms of several embodiments. In describing these embodiments, for the sake of clarity and compactness throughout the supporting figures, elements with identical or similar functionality have been assigned the same numbers.

In the discussion of certain mathematical relationships, certain variable values are discussed by way of illustration. However, the invention is not intended to be limited to the specific embodiments described below.

Recent advances in integrated piezoelectric resonator technology have brought about integrated Bulk Acoustic Wave (BAW) resonators. BAW resonators are fabricated on integrated circuit (IC) wafers or other wafers or substrate using monolithic deposition methods and can be quite compact. Aluminum Nitride (AlN), Zinc Oxide (ZnO) or other piezoelectric film arrangements can be deposited with electrode metals and form piezoelectric resonators that may produce frequencies in the general range of approximately 500 MHz to approximately 5000 MHz, while occupying a minimal die area, e.g. 200 μm×200 μm. Integrated BAW resonators are well known to those skilled in the art and are not described in detail herein. Exemplary integrated BAW resonators are disclosed in U.S. Pat. Nos. 8,089,195 and 8,222,795, both of which are incorporated herein by reference.

An integrated BAW resonator may be assembled with a semiconductor die in a low-cost small-size plastic IC package. In contrast, a quartz resonator must operate in a sealed cavity, which requires an expensive and larger hermetic package such as a ceramic package.

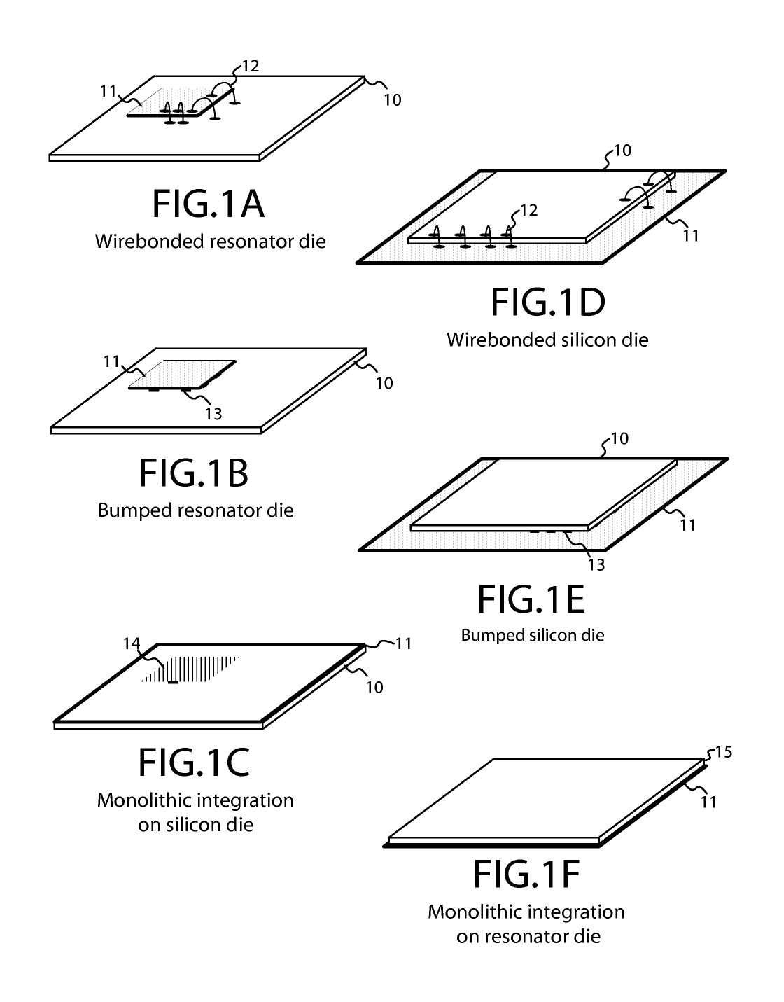

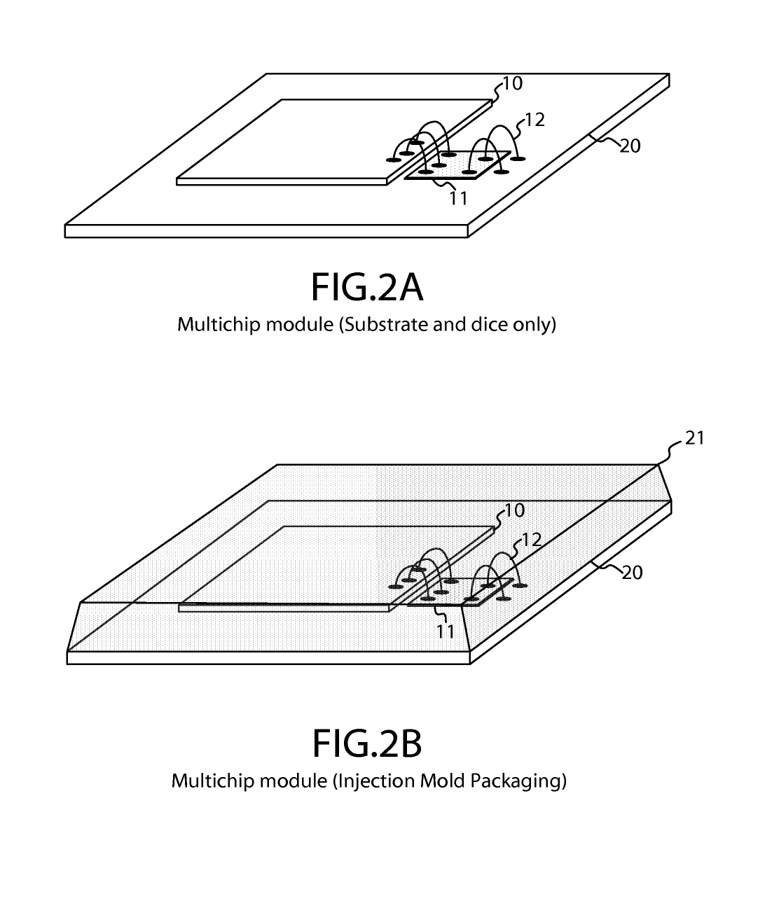

The monolithic integration of BAW resonators with silicon or other monolithic semiconductor devices can be accomplished in a variety of ways, as is well known to those skilled in the art. Such monolithically integrated assemblies provide an array of advantages such as being placed in a single package. FIGS. 1A-1F and FIGS. 2A-2B illustrate various concepts detailing the integration of BAW resonator die with the semiconductor die within a single package. This package can be of Chip Scale (CSP), or of a larger scale such as Land Grid Array (LGA), Quad Frame No-lead (QFN), etc.

For example, certain Chip-Scale-Packaging (CSP) approaches are illustrated in FIGS. 1A-1F. FIG. 1A shows a BAW resonator die 11 (i.e. a substrate that includes at least one BAW resonator) attached to a larger a semiconductor die 10 that includes active and passive devices and electrically connected to the semiconductor die by wirebonding 12. FIG. 1B shows a BAW resonator die 11 attached and electrically connected by flip-chip bumping 13 onto a semiconductor die 10. FIG. 1C shows a BAW resonator 14 that is monolithically integrated onto a semiconductor die 10. The resonator 14 occupies only a fraction of the semiconductor die 10. FIG. 1D shows a smaller semiconductor die 10 attached to and electrically connected by wirebonding 12 to a BAW resonator die 11. FIG. 1E shows a smaller semiconductor die 10 that is attached and electrically connected to a BAW resonator die 11 by flip-chip bumping 13. FIG. 1F shows a semiconductor circuit 15 monolithically integrated onto a BAW resonator die 11.

A Multi-Chip-Module (MCM) arrangement is depicted in FIGS. 2A-2B, where a semiconductor die 10 and a BAW resonator die are attached to a common substrate 20 and electrically connected to each other by wirebonding 12. A transfer-molded protective cover 21 may be provided over the structure.

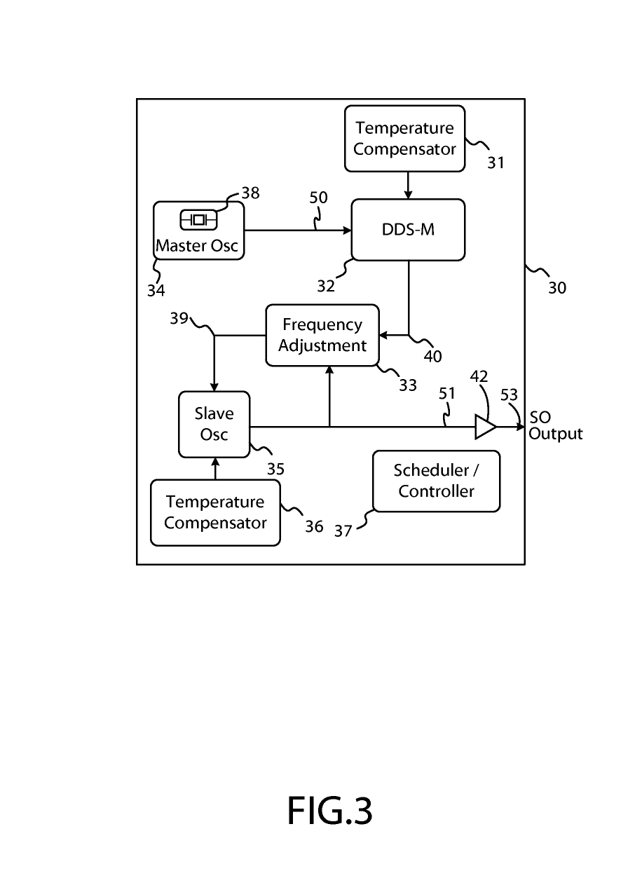

FIG. 3 illustrates a block diagram of an integrated reference frequency generator 30 according to some aspects of the invention. The integrated reference frequency generator 30 includes a master oscillator circuit 34, a slave oscillator circuit 35, temperature compensator circuits 31, 36, a direct digital synthesizer (DDS) circuit 32 (labeled DDS-M because it is connected to the master oscillator circuit 34), a frequency adjustment circuit 33, a scheduler/controller circuit 37. The master oscillator circuit 34 includes an integrated BAW resonator 38. An output signal 50 of the master oscillator circuit 34 clocks the DDS-M circuit 32. The temperature compensator circuit 31 monitors the temperature of (or in the vicinity of) the master oscillator circuit 34 (including the temperature of the integrated BAW resonator 38), and provides a digital frequency adjustment value to the DDS-M circuit 32. The DDS-M circuit 32 outputs a master reference frequency signal 40 to the frequency adjustment circuit 33. The frequency adjustment circuit 33 compares the frequency of the master reference frequency signal to the frequency of an output signal 51 of the slave oscillator circuit 35. The slave oscillator circuit 35 receives as input a frequency adjustment signal 39 that is output from the frequency adjustment circuit 33. The output signal 51 of the slave oscillator circuit 35 is buffered by buffer circuit 42 and provided as an output 53 of the integrated reference frequency generator 30. The temperature compensator circuit 36 monitors the slave oscillator circuit 35 and provides direct frequency adjustment to the slave oscillator circuit 35 as needed.

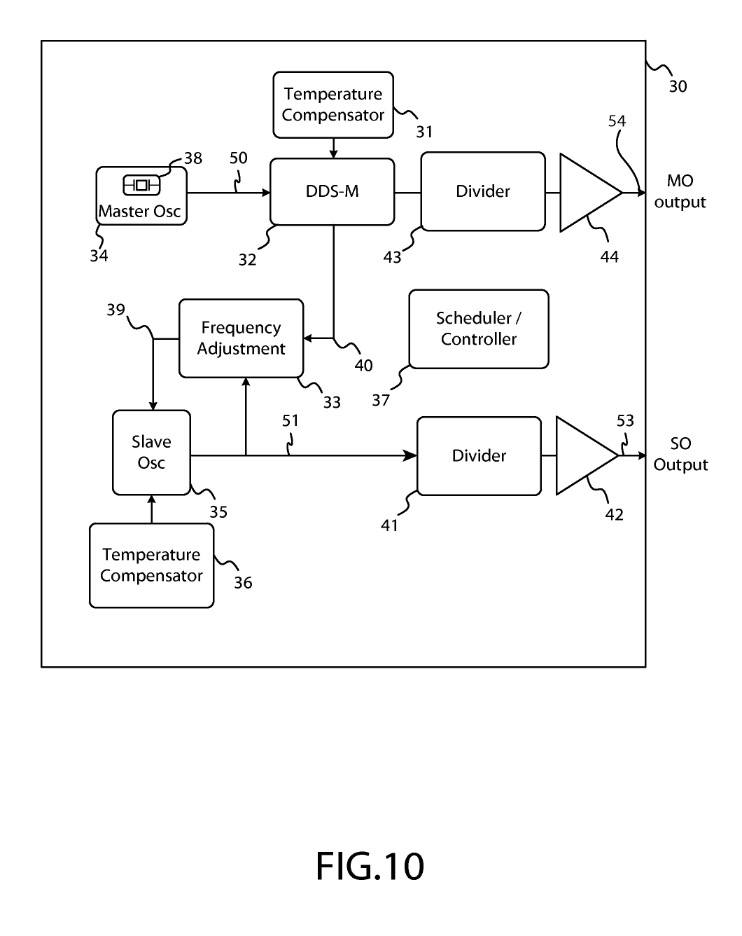

During operation of the integrated frequency generator 30, the slave oscillator circuit 35 (having relatively low power consumption and poor stability, compared to the master oscillator circuit 34) generates the output signal 51 that may be frequency-divided (see FIG. 10) to produce the output signal 53 (SO Output) of the integrated reference frequency generator 30 with a given frequency. The master oscillator circuit 34 is periodically powered up and enabled and its output signal 50 is used to adjust the frequency of the slave oscillator circuit 35 such that the slave oscillator circuit 35 achieves better frequency stability than if the slave oscillator circuit 35 were free-running. The integrated reference frequency generator 30 achieves a lower power consumption than if its output signal 53 (SO Output) were generated by the master oscillator circuit 34 operating continuously. Operation of the master oscillator circuit 34, the DDS-M circuit 32 and the frequency adjustment circuit 33 is determined by the scheduler/controller circuit 37. Various methods of frequency adjustment are described in the different embodiments illustrated in the figures and described herein.

The master oscillator circuit 34 is the main frequency reference and may be constructed as a monolithic oscillator with an output frequency in the range of approximately 100 MHz to approximately 10 GHz. The frequency of the master oscillator circuit 34 is primarily determined by the integrated BAW resonator 38. Integrated BAW resonators may be fabricated on silicon or other wafer types using monolithic fabrication methods and are much smaller than quartz resonators.

As described above, integrated BAW resonators lend themselves to complete integration either within an integrated circuit package (i.e. multi-die co-packaging) or on the same die (i.e. complete monolithic integration). This is a significant advantage over prior-art solutions that require a quartz crystal or similar resonator in an expensive package.

Another significant advantage of master oscillator circuit 34 is that it has a very fast turn-on transition time, ranging from a few microseconds to tens of microseconds, because it comprises integrated BAW resonator 38 as a resonant tank. This feature of the master oscillator circuit 34 is leveraged in the intermittent adjustment of the slave oscillator circuit 35 described below.

Another advantage of the integrated reference frequency generators disclosed herein is that they can be integrated monolithically or co-packaged with sensors that comprise a BAW resonator. Example devices that can be integrated with the integrated reference frequency generator include pressure sensors, acoustic microphones, acceleration or vibration sensors, physical, chemical and biological sensors, as well as electronic devices that comprise a BAW resonator, such as RF filters, RF transmitters, RF receivers and RF other circuits, etc.

The output frequency of the slave oscillator circuit 35 is in the range of approximately 1 kHz to a few hundred kHz (e.g. for applications real-time clock applications) and from approximately 1 MHz to a few hundred of MHz (e.g. for CPU clocking applications). Since the slave oscillator circuit 35 operates continuously, the slave oscillator circuit 35 is preferably designed to have a low power consumption. As a consequence, the slave oscillator circuit 35 features poor absolute and temperature-dependent frequency stability when it operates in free-run mode. To correct this excessive frequency drift, the slave oscillator circuit 35 is periodically adjusted by tuning one or more of its frequency determining elements, based on the frequency adjustment signal 39. The frequency adjustment signal 39 is determined based on a comparison of the slave oscillator output signal 51 with the master reference frequency signal 40, as described below.

The master oscillator circuit 34 features superior frequency stability compared to the slave oscillator circuit 35. The DDS-M circuit 32, e.g. similar to the one described in U.S. Pat. No. 8,242,850, processes the master oscillator output signal 50 to synthesize a master reference frequency signal 40 that is output from the DDS-M circuit 32. Depending on requirements, the DDS-M circuit 32 may divide the frequency of the master oscillator circuit 34 output signal 50 by fractional division techniques or integer division techniques. Optionally, the DDS-M circuit 32 may use phase interpolation techniques to achieve a lower output jitter. The master reference frequency signal 40 and the slave oscillator output signal 51 are applied to the frequency adjustment circuit 33 which produces the frequency adjustment signal 39. The frequency adjustment signal is applied directly to the slave oscillator circuit 35 and changes the frequency or phase of the slave oscillator output signal 51.

The temperature compensator circuit 36 senses the operating temperature of the slave oscillator circuit 35, and may independently adjust the slave oscillator frequency by adjusting the value(s) of the slave oscillator's frequency determining element(s). The operation of the temperature compensator circuit 36 may be dependent of or independent of the scheduler/controller circuit 37.

Note that, for the sake of conciseness, in parts of this document where clarity is not affected, a signal and the frequency of that signal are referred to interchangeably.

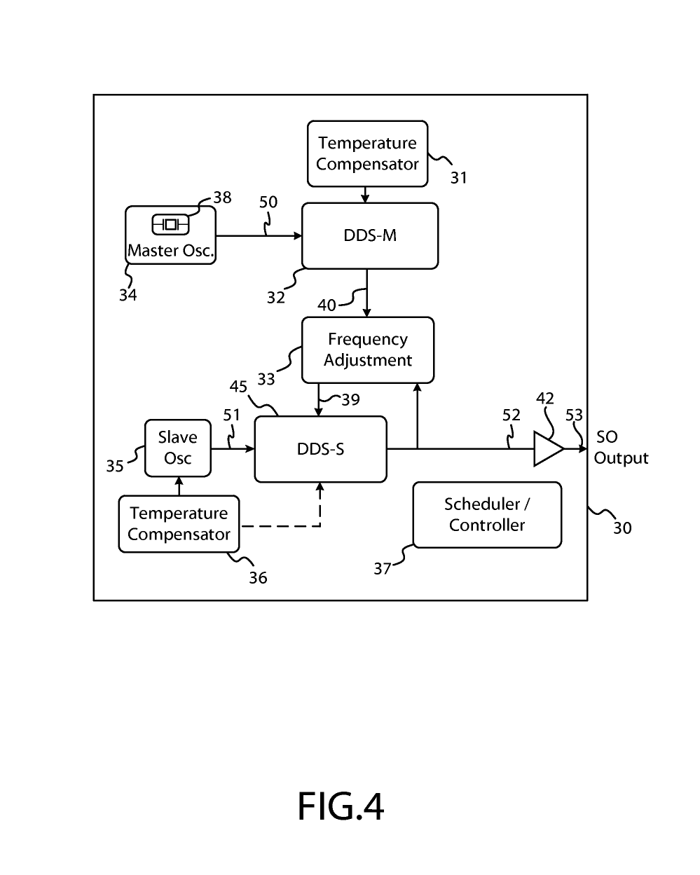

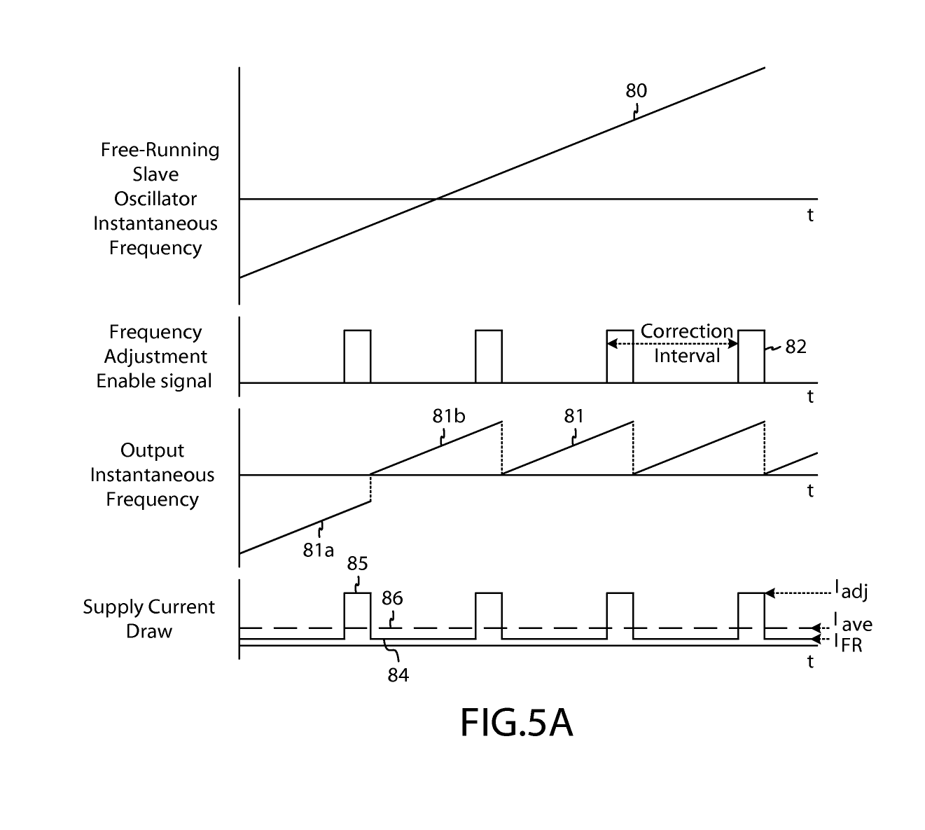

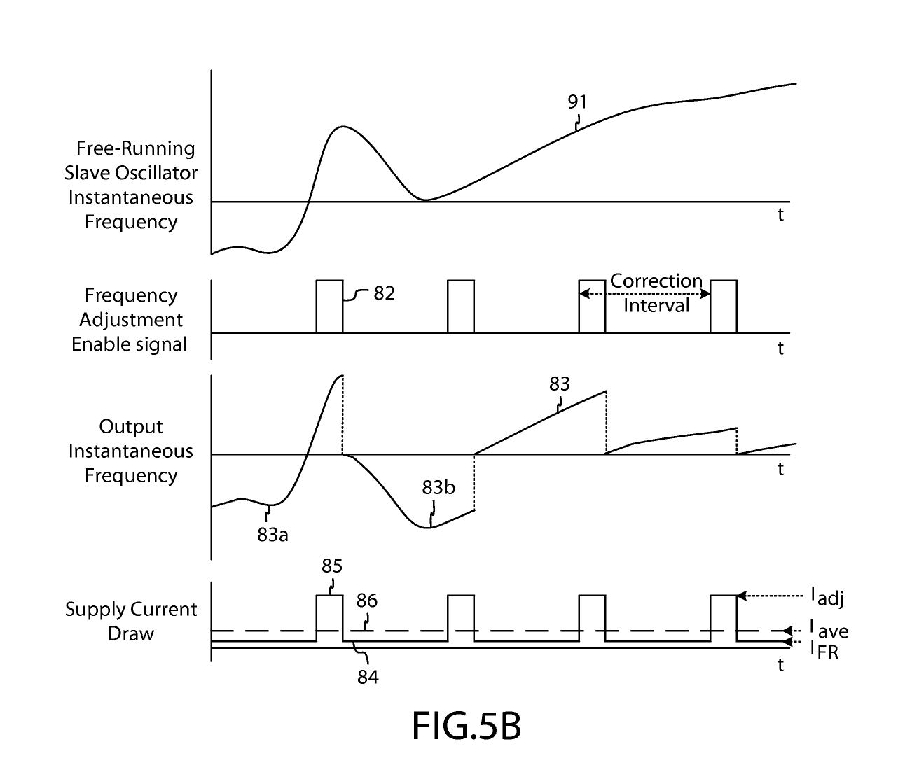

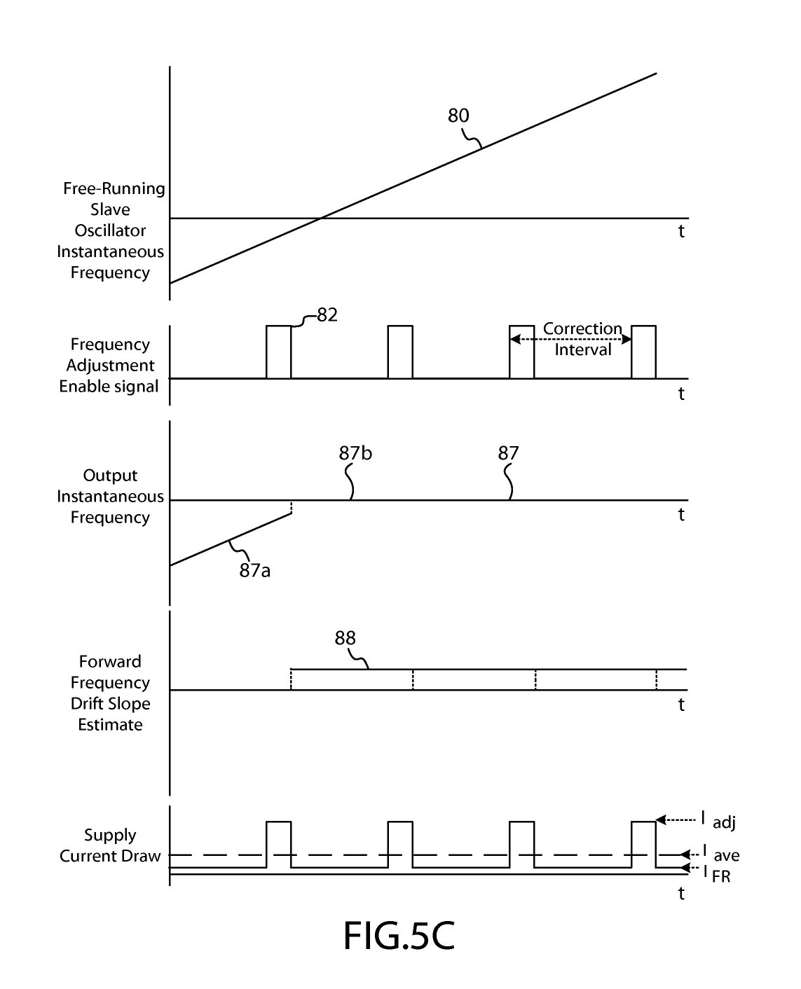

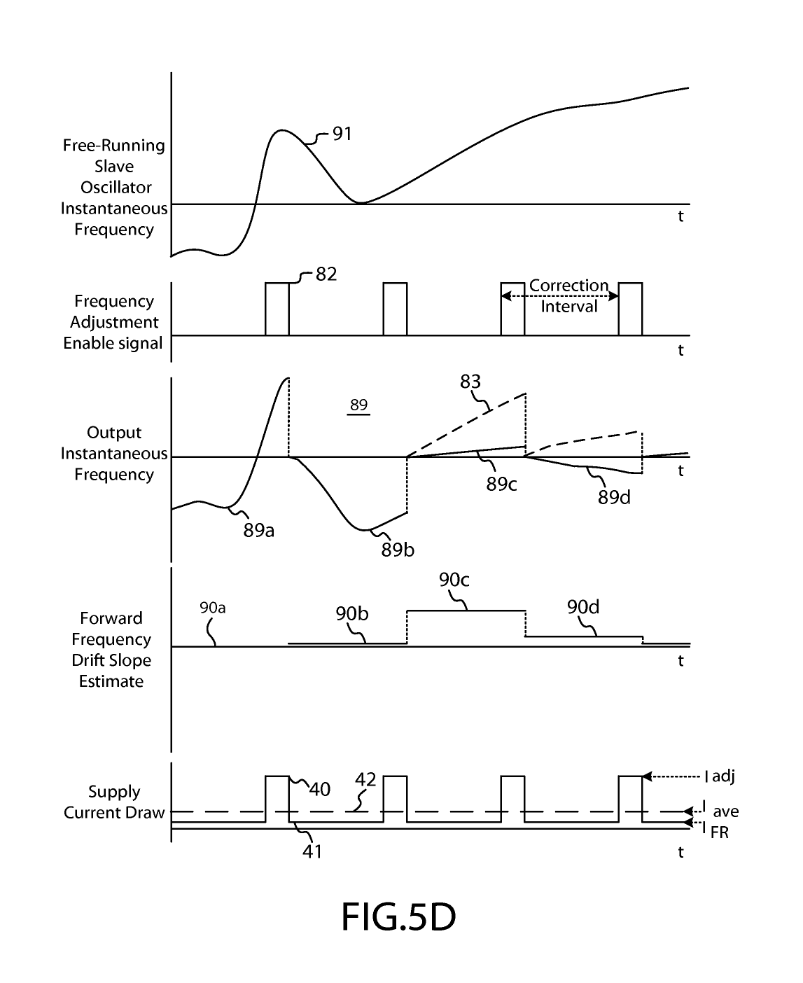

FIG. 4 illustrates a block diagram of an integrated reference frequency generator 30 according to some aspects of the invention. The reference frequency generator 30 of FIG. 5 is similar to the reference frequency generator 30 of FIG. 3 with some modifications. A DDS circuit 45 (labeled DDS-S because it is connected to the slave oscillator circuit 35) is driven by the slave oscillator circuit output 51 and receives the frequency adjustment signal 39 from the frequency adjustment circuit 33. The output signal 52 of the DDS-S circuit 45 is fed to the frequency adjustment circuit 33 and is also buffered by the buffer circuit 42 to provide the output signal 53 of the integrated reference frequency generator 30. The temperature compensator circuit 36 may communicate with the DDS-S circuit 45 as well as the slave oscillator circuit 35.

The output signal 52 of the DDS-S circuit 45 is compared in the frequency adjustment circuit 33 with the master reference frequency signal 40 output from the DDS-M circuit 32. The output frequency adjustment is accomplished by changing the divisor (or division ratio or modulus) of the DDS-S circuit 45, rather than by directly altering the frequency of the slave oscillator circuit 35 as described with reference to FIG. 3. The temperature compensator circuit 36 is used intermittently to directly adjust the frequency determining element(s) of the slave oscillator circuit 35, as described with reference to FIG. 3. Alternately, the temperature compensator circuit 36 can adjust the fractional divisor of DDS-S circuit 45 resulting in a temperature-controlled value of the fractional frequency division ratio.

The embodiment illustrated in FIG. 4 may be more suitable for a frequency generator in which the frequency of the slave oscillator circuit 35 output signal 51 is more than twice the frequency of the integrated reference frequency generator 30 output signal 53. An advantage of this embodiment is that the jitter of output signal 53 may be optimized for lower power with no additional consideration for tuning.

The master oscillator circuit 34 operates in the approximate range of approximately 500 MHz to approximately 5000 MHz and consumes more power than the slave oscillator circuit 35. On the other hand, the frequency stability of the master oscillator circuit 34 is much better than that of the slave oscillator circuit 35. Thus, operating the master oscillator circuit 34 intermittently conserves power and with careful design can ensure that the slave oscillator frequency stability remains within specified bounds.

The intermittent operation of the master oscillator circuit 34, the DDS-M circuit 32 and the frequency adjustment circuit 33 results in lower power consumption over the case where the adjustment is continuously applied to the slave oscillator circuit 35. The total average power is given as follows:

P_{0avg}=P_{SO}+P_{CORR} Eq. 1

where P_{SO} is the average power of slave oscillator circuit 35, and the scheduler/controller circuit 37, and P_{CORR} is the average power of the adjustment circuitry, including the master oscillator circuit 34, the DDS-M circuit 32, and the frequency adjustment circuit 33. As mentioned above, the master oscillator circuit 34, which includes integrated BAW resonator 38, has a rapid turn-on time which may significantly reduce the additional average power consumed by the adjustment circuitry.

Battery-operated and real-time clock (RTC) devices may require frequency generation at extremely low power (e.g. about 25 microwatts) while maintaining high frequency accuracy (e.g. 10 ppm). For example, a relaxation oscillator used as the slave oscillator circuit 35 operates at the typical RTC frequency of 32.768 kHz with a combination of a resistor and a capacitor as frequency-determining elements. Such a slave oscillator draws 5 μA from a 2.7V supply, i.e. consumes P_{SO}=13.5 uW, but does not have the required frequency stability and requires periodic adjustment. In addition, a master oscillator circuit 34 that includes a 2 GHz integrated BAW resonator 38 may operate at 2.7V and draw 2 mA, i.e. consume 5.4 mW, when enabled. To produce a reference signal at 32.768 kHz, the DDS-M circuit 32 divides the frequency of the 2 GHz signal by 61035.15625. When enabled, the DDS-M circuit 32 also draws 2.4 mA at 2.7V, i.e. consumes 6.5 mW. The frequency adjustment circuit 33 consumes an additional 0.1 mW when enabled. The operational duty cycle of the frequency adjustment circuit 33 along with the master oscillator circuit 34 and the DDS-M circuit 32 determines the additional power consumption above the baseline of 13.5 μW. So if, for example, the adjustment happens once a second and is completed within 1 msec, then the duty cycle of 0.1% results in an additional P_{CORR}=(5.4 mW+6.5 mW+0.1 mW)×0.001=12 μW. This results in a total average power consumption of P_{0avg}=13.5 μW+12 μW=25.5 μW.

An additional benefit of the intermittent operation of the adjustment circuitry is that the aging of the master oscillator circuit 34 and the integrated BAW resonator 38 is slowed down because these devices are only enabled during a fraction of the operating time of integrated reference frequency generator 30. Such low duty-cycle operation not only enhances the frequency stability of the master oscillator circuit 34, but also can significantly extend the serviceability of the integrated reference frequency generator 30.

Another significant advantage of the embodiments illustrated in FIGS. 3 and 4 is that the frequency tolerance of the slave oscillator circuit 35 is significantly improved by tracking the accuracy of the master oscillator circuit 34. For example, as shown in FIG. 3, the instantaneous frequency deviation Δf_{OUT}(t) observed at the output 53 of the integrated reference frequency generator 30 is given as follows:

Δf_{OUT}(t)=Δf_{OUT}/Δt*[t−t_{adj}] Eq. 2

where Δf_{OUT}/Δt is the frequency drift slope (assuming linear deviation with time), t is a given time instant, and t_{adj} is the time instant of the last adjustment of the slave oscillation frequency. The estimated instantaneous frequency deviation Δf_{OUT}(t) may then be converted to the frequency adjustment signal 39, which is applied directly to the slave oscillator circuit 35.

In the embodiment shown in FIG. 4, since the slave oscillator circuit 35 is free-running and the output frequency is adjusted through the DDS-S circuit 45, the instantaneous frequency deviation Δf_{OUT}(t) given by equation 2 designates the instantaneous frequency deviation observed at the output 52 of the DDS-S circuit 45.

Based on the above relationship, for a given maximum known frequency drift slope and a desired maximum frequency deviation requirement, the frequency adjustment interval Δt_{adj} is given as follows:

Δt_{adj}≦1/max[Δf_{OUT}/Δt]*Δf_{OUTmax} Eq. 3

where max [Δf_{OUT}/Δt] is the maximum expected frequency drift slope of the unadjusted slave oscillator circuit 35, and Δf_{OUTmax} is the specified maximum frequency deviation.

The scheduler/controller circuit 37 determines the time instants at which adjustments are performed by controlling the operation of the master oscillator circuit 34, the DDS-M circuit 32 and the frequency adjustment circuit 33. There are several possible regimes under which the scheduler/controller circuit 37 can operate. For example, the frequency adjustment process can be triggered by: i) a change of operating or ambient temperature, ii) a predetermined elapsed time, iii) user control, or iv) a combination of any of the above and other criteria.

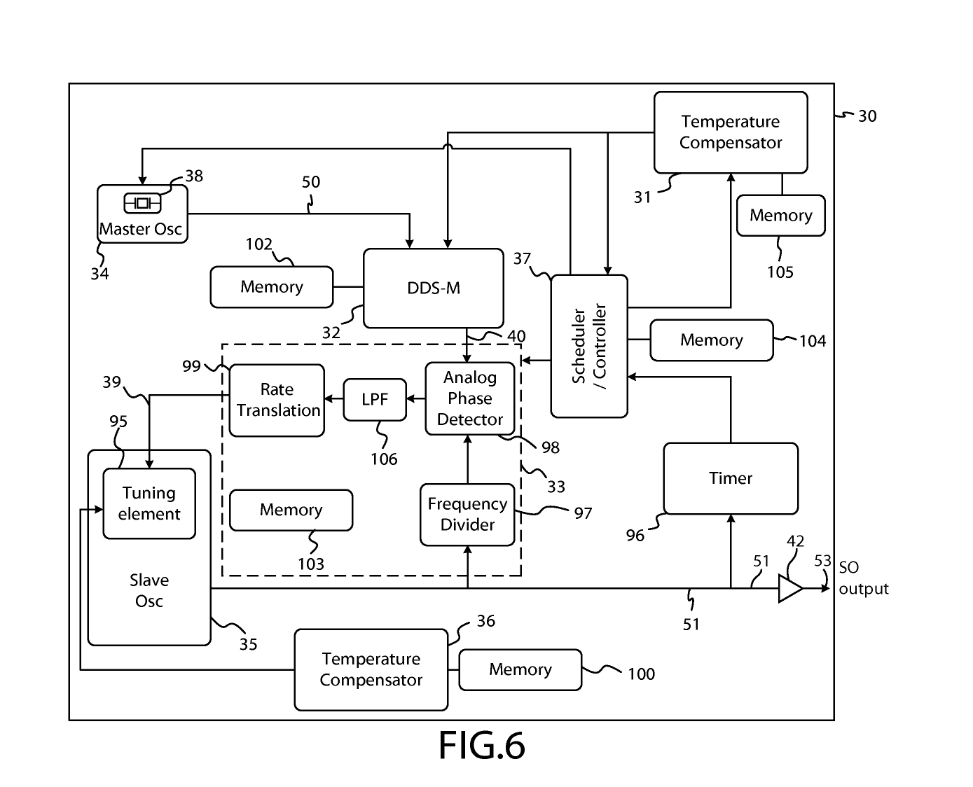

In one embodiment, given a maximum possible frequency deviation slope and a maximum frequency deviation specification, the scheduler/controller circuit 37 is triggered by a timer 96 (shown in FIGS. 6-9), which may be implemented with a large-ratio frequency divider. The timer 96 counts N pulses of the slave oscillator circuit 35 output signal 51 (or, in the architecture such as presented on FIG. 4, the timer 96 counts N pulses of the DDS-S circuit 45 output signal 52) before it initiates the adjustment operation with N given by:

N≦(f_{OUT}+Δf_{OUTmax})*Δf_{OUTmax}/max[Δf_{OUT}/Δt] Eq. 4

Variations of this embodiment are illustrated in FIGS. 6-9, as discussed below.

In another embodiment described with reference to FIGS. 3 and 4, given the dependency of the frequency drift on temperature variation, the die temperature is sensed by the temperature compensator circuit 36 every Δt_{adj} seconds. A frequency adjustment takes place according to a model of the frequency deviation vs. temperature. For example, the model can be described through a piecewise linear function, or another function that requires a low computational complexity, although any function can be used. In the embodiment illustrated in FIG. 3, the adjustment value is applied directly to the slave oscillator circuit 35 as the frequency adjustment signal 39. In the embodiment illustrated in FIG. 4, the frequency adjustment value can also be provided as the frequency adjustment signal 39 to the DDS-S circuit 45 and implemented as a change in the divisor.

FIG. 5A shows the frequency adjustment process for a slave oscillator circuit 35 whose output frequency drifts linearly as a function of time. For the sake of clarity, FIG. 5A illustrates the adjustment process for the architecture presented on FIG. 4 where the slave oscillator circuit 35 is free-running (assuming the temperature compensator circuit 36 is disabled) and the frequency adjustment is performed via the DDS-S circuit 45. FIG. 5A comprises four graphs. The top graph shows the free-running slave oscillator instantaneous frequency 80, which is the frequency of the slave oscillator 35 output signal 51 drifting linearly as a function of time. The second graph from the top shows the frequency adjustment enable signal 82, which is a signal generated by the scheduler/controller circuit 37. The third graph from the top shows the output instantaneous frequency 81, which is the frequency of the output signal 53 of the integrated reference frequency generator 30. The output instantaneous frequency 81 before the first temperature drift adjustment is denoted as 81a; the output instantaneous frequency after the first temperature drift adjustment is denoted as 81b. Finally, on the bottom graph, curves 84, 85, 86 show the supply current drawn by circuits that compose the integrated reference frequency generator 30 under various operating conditions.

As stated above, the free-running slave oscillator instantaneous frequency 80 drifts linearly over time. The output instantaneous frequency 81 is periodically adjusted to a nominal output frequency at times designated by pulses in the frequency adjustment enable signal 82. The output instantaneous frequency 81 is adjusted according to the observed difference between the frequency of the master reference frequency signal 40 and the frequency of the output signal 52 of the DDS-S circuit 45 by the frequency adjustment circuit 33 via the DDS-S circuit 45. Immediately after power-up, while the drift compensation is not active, the instantaneous output frequency 81a follows the free-running slave oscillator instantaneous frequency 80. Then, the first frequency adjustment is performed, and the instantaneous output frequency 81 is adjusted to its nominal value. Then, the free-running slave oscillator instantaneous frequency 80 continues to drift linearly, and the output instantaneous frequency 81b drifts again from the nominal frequency value. The frequency adjustment process is repeated periodically. The maximum frequency deviation is determined by the adjustment interval and the slave oscillator circuit 35 output signal 51 frequency drift slope.

The instantaneous supply current drawn by the integrated reference frequency generator 30 is also graphed in FIG. 5A. The current 84 (I_{FR}) drawn when only the slave oscillator circuit 35, the frequency divider circuit 41, the buffer circuit 42 and the scheduler/controller circuit 37 are enabled is lower than the peak of current 85 (I_{adj}) drawn when the master oscillator circuit 34, the DDS-M circuit 32, and the frequency adjustment circuit 33 are enabled. The average supply current 86 (Iₐᵥₑ) is determined by the two current values, the master oscillator power-on time duration and the adjustment period, as described below.

FIG. 5B shows the frequency adjustment process for a slave oscillator circuit 35 that is free-running (as illustrated in FIG. 5A and explained above) whose output frequency drifts in a random walk fashion as a function of time. FIG. 5B includes four graphs. The top graph shows the free-running slave oscillator instantaneous frequency 91, which is the frequency of the slave oscillator 35 output signal 51 drifting in a random walk fashion as a function of time. The second graph from the top shows the frequency adjustment enable signal 82, which is a signal generated by the scheduler/controller circuit 37, as in FIG. 5A. The third graph from the top shows the output instantaneous frequency 83, which is the frequency of the output signal 53 of the integrated reference frequency generator 30. The output instantaneous frequency 83 before the first temperature drift adjustment is denoted as 83a; the output instantaneous frequency 83 after the first temperature drift adjustment is denoted as 83b. Finally, in the bottom graph, curves 84, 85, 86 show the supply current drawn by circuits that compose the integrated reference frequency generator 30 under various operating conditions, as on FIG. 5A.

As stated above, the free-running slave oscillator instantaneous frequency 91 drifts in a random walk fashion over time. The frequency adjustment process is periodic with an adjustment interval designated by pulses in the frequency adjustment enable signal 82. Immediately after power-up, while the drift compensation is not active, the instantaneous output frequency 83a follows the free-running slave oscillator instantaneous frequency 91. Then, the first frequency adjustment is performed, and the output instantaneous frequency 83 is adjusted to the nominal output frequency. Then, the instantaneous output frequency 83b drifts again in a random walk fashion until the adjustment process is repeated.

The supply current plots show that the average current draw 86 (Iₐᵥₑ) is slightly higher than the slave oscillator supply current 84 (I_{FR}) but much lower than the peak of current 85 (I_{adj}) drawn during the frequency adjustment process.

According to an aspect of the invention illustrated on FIGS. 5C and 5D, the frequency drift compensation can be applied forward in time, assuming a constant frequency drift slope for the duration of the frequency adjustment interval.

FIG. 5C shows the frequency adjustment process with forward adjustment wherein the slave oscillator circuit 35 is free running (as illustrated in FIGS. 5A and 5B and explained above) and its output frequency drifts in linear fashion as a function of time for ease of demonstration, as illustrated in FIG. 5A.

FIG. 5C includes five graphs. The top graph shows the free-running slave oscillator instantaneous frequency 80, which is the frequency of the slave oscillator 35 output signal 51 drifting linearly as a function of time. The second graph from the top shows the frequency adjustment enable signal 82, which is a signal generated by the scheduler/controller circuit 37, as in FIGS. 5A and 5B. The third graph from the top shows the output instantaneous frequency 87, which is the frequency of the output signal 53 of the integrated reference frequency generator 30. The output instantaneous frequency 87 before the first temperature drift adjustment is denoted as 87a; the output instantaneous frequency 87 after the first temperature drift adjustment is denoted as 87b. The fourth graph from the top shows the forward frequency drift slope estimate 88, which is computed by the frequency adjustment circuit 33 or the temperature compensator circuit 36. Finally, on the bottom graph, curves 84, 85, 86 show the supply current drawn by circuits that compose the integrated reference frequency generator 30 under various operating conditions, as in FIGS. 5A and 5B.

As stated above, the free-running slave oscillator instantaneous frequency 80 drifts linearly over time. The frequency adjustment is periodic with an adjustment interval designated by pulses in the frequency adjustment enable signal 82. The difference between this scheme and the schemes illustrated in FIGS. 5A and 5B is that both the frequency error and the frequency drift slope are computed at the end of each adjustment interval and used by the frequency adjustment circuit 33 or temperature compensator circuit 36 such that the projected linear frequency drift error is cancelled for the duration of the next adjustment interval. The forward frequency drift slope estimate 88 is an estimate of the drift of the instantaneous output frequency 87 over time.

At power up, as the drift compensation is not active, the output instantaneous frequency 87a follows the free-running slave oscillator instantaneous frequency 80. Then, the first frequency adjustment is performed, and the output instantaneous frequency 87 is adjusted to its nominal value and the computed forward frequency drift slope estimate 88 is forward-applied via a frequency adjustment mechanism which can be implemented, for example, in the frequency adjustment circuit 33 or the temperature compensator circuit 36 or both. Then, the instantaneous output frequency 87b drifts again in linear fashion until the frequency adjustment process is repeated. The power consumption is graphed as in FIGS. 5A and 5B.

The forward frequency adjustment method can achieve better frequency stability over short adjustment intervals compared to simpler adjustment methods.

FIG. 5D shows the forward-frequency adjustment process applied to the free-running slave oscillator (as illustrated in FIGS. 5A, 5B and 5C and explained above) whose output frequency drifts in a random walk fashion as a function of time, as depicted on FIG. 5B. FIG. 5D includes five graphs. The top graph shows the free-running slave oscillator instantaneous frequency 91, which is the frequency of the slave oscillator 35 output signal 51 drifting in a random walk fashion over time. The second graph from the top shows the frequency adjustment enable signal 82, which is a signal generated by the scheduler/controller circuit 37, as in FIGS. 5A, 5B and 5C. The third graph from the top shows the output instantaneous frequency 89, which is the frequency of the output signal 53 of the integrated reference frequency generator 30. The output instantaneous frequency 89 before the first temperature drift adjustment is denoted as 89a; the output instantaneous frequency after the first, second and third temperature drift adjustments is denoted as 89b, 89c and 89c respectively. The fourth graph from the top shows the forward frequency drift slope estimate 90, which is computed by frequency adjustment circuit 33 or the temperature compensator circuit 36. The forward frequency drift slope estimate 90 before the first temperature drift adjustment is denoted as 90a; the forward frequency drift slope estimate 90 after the first, second and third temperature drift adjustments is denoted as 90b, 90c and 90c respectively. Finally, on the bottom graph, curves 84, 85, 86 show the supply current drawn by circuits that compose the integrated reference frequency generator 30 under various operating conditions, as in FIGS. 5A, 5B and 5C.

At power up, the output instantaneous frequency 89 follows the free-running slave oscillator instantaneous frequency as the drift compensation is not active. Then, the first frequency adjustment is performed, and the output instantaneous frequency 89 is adjusted to its nominal value and the forward frequency drift slope estimate 88 is computed (in this example, the value of the forward frequency drift slope estimate computed during the first frequency adjustment is 88b) and is used to forward adjust the output instantaneous frequency 89 until the next adjustment operation. Then, the instantaneous output frequency 89b drifts again in a random walk fashion until the frequency adjustment process is repeated. For comparison, purpose, the third graph from the top shows the output instantaneous frequency 89 obtained with feed-forward drift adjustment and the output instantaneous frequency 83 (shown in dashed lines) obtained without feed-forward drift adjustment as illustrated in FIG. 5B. The deviation from nominal of the output instantaneous frequency is lower with the feed-forward drift adjustment method than without it. The power consumption graph shows the benefit of the frequency adjustment scheme, as in FIGS. 5A, 5B and 5C.

Referring back to FIGS. 3 and 4, additional frequency adjustment methods are described. In a first method, the temperature compensator circuit 31 senses the temperature of master oscillator circuit 34 and the integrated BAW resonator 38, and adjusts the divisor of the DDS-M circuit 32 in order to cancel the temperature-induced frequency drift of the master oscillator circuit 34. Adjusting the divisor of the DDS-M circuit 32 enhances the accuracy of the master reference frequency signal 40 before it is processed by the frequency adjustment circuit 33. In a second method, the temperature compensator circuit 36 directly adjusts the frequency determining elements of the slave oscillator circuit 35 and/or the divisor of the DDS-S circuit 45 to reduce the temperature-induced frequency drift of slave oscillator circuit 35.

FIGS. 6-9 illustrate functional block diagrams of embodiments of the integrated reference frequency generator 30 in accordance with aspects of the invention and with reference to FIGS. 3 and 4.

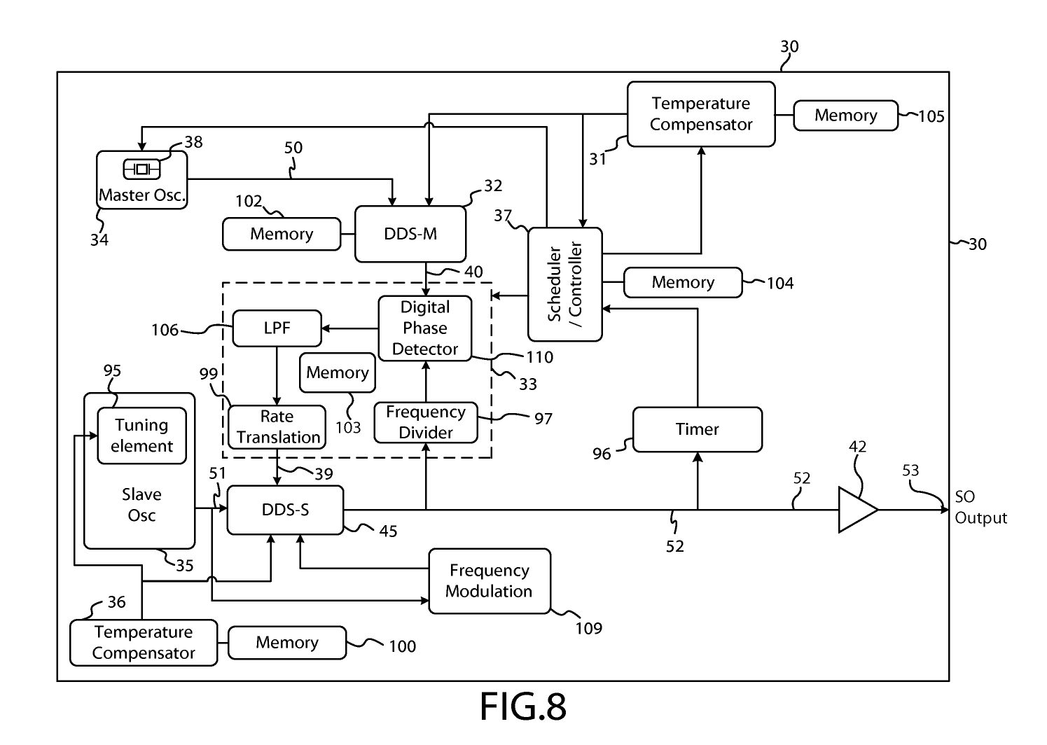

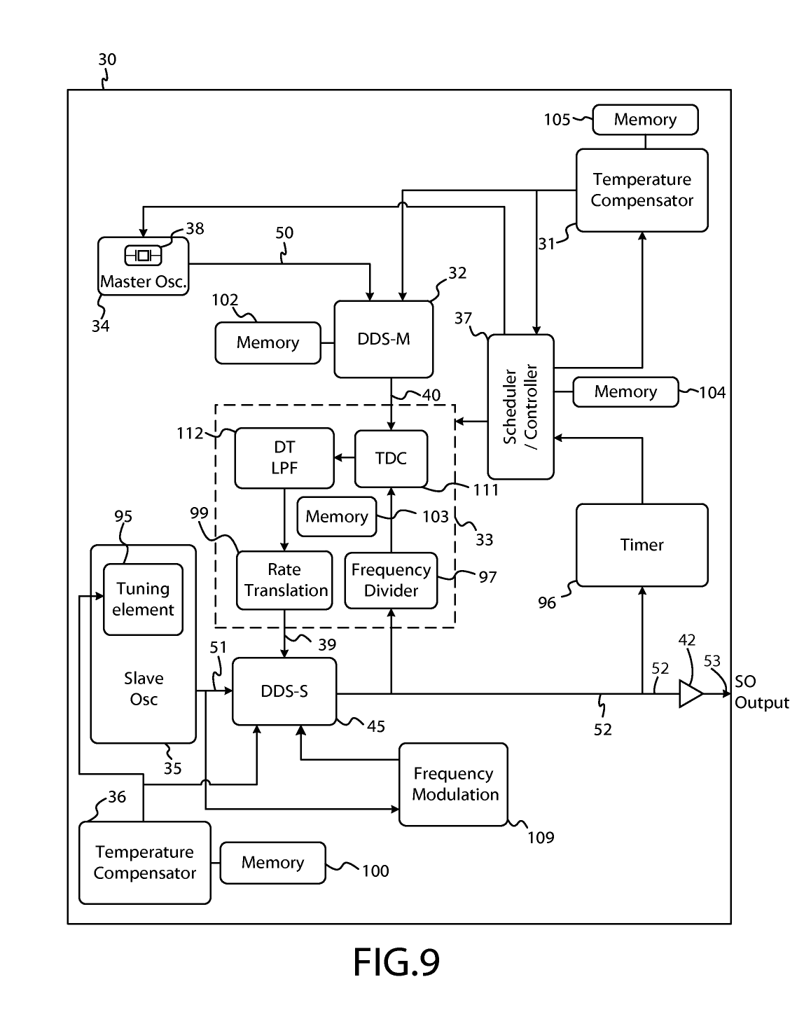

To facilitate a detailed discussion of the frequency adjustment capabilities of the invention, the embodiments of FIGS. 6-9 include detailed implementations of the frequency adjustment circuit 33. Additional elements also include a memory 100 for the slave oscillator temperature compensator circuit 36, a memory 104 for the scheduler/controller circuit 37, a memory 105 for the master oscillator temperature compensator circuit 31, a memory 102 for the DDS-M circuit 32, a memory circuit 103 for the frequency adjustment circuit 33, a timer circuit 96 and a frequency modulation circuit 109 that is clocked by the slave oscillator circuit 35 and adjusts the divisor of the DDS-S circuit 45 in FIGS. 8 and 9. Also, a tuning element 95 of the slave oscillator circuit 35 is shown as a distinct circuit within the slave oscillator circuit 35 to illustrate a locus of frequency adjustment of the slave oscillator circuit 35.

The frequency of the output signal 50 of the master oscillator circuit 34 and the frequency of the master reference frequency signal 40 are measured, and calibrated if needed, during or after manufacturing, and the relevant parameters are stored in the memory 102 of the DDS-M circuit 32. The relationship of the master frequency drift to the ambient temperature variation can be captured and modeled by a piece-wise linear function or other similar function of low circuit complexity, or any other function. The temperature compensator circuit 31 is enabled by the scheduler/controller circuit 37 during the frequency adjustment window and outputs a digitized frequency adjustment value to the DDS-M circuit 32 so that the frequency of the master reference frequency signal 40 is intermittently adjusted.

According to a different aspect of the invention, the temperature compensator circuit 31 is operated intermittently and enables the scheduler/controller circuit 37 when the measured temperature exceeds a previously measured temperature by a certain value that requires immediate frequency adjustment.

The scheduler/controller circuit 37 controls the operation of the master oscillator circuit 34, the temperature compensator circuit 31 and the frequency adjustment circuit 33. The timer 96, which may be implemented with a large-ratio frequency divider, is clocked by the slave oscillator output signal 51 and signals the scheduler/controller circuit 37. The scheduler/controller circuit 37 periodically enables the frequency adjustment circuit 33 along with the master oscillator circuit 34 and the DDS-M circuit 32. The scheduler/controller circuit 37 also enables the temperature compensator circuit 31 in the master oscillator path to introduce additional frequency adjustment to the DDS-M circuit 32 and the temperature compensator circuit 36 in the slave oscillator path. The scheduler/controller circuit 37 enables the frequency adjustment process (implemented by the frequency adjustment circuit 33 and other circuits as required) intermittently, periodically or not periodically, with a schedule that can be deterministic or pseudo-random or random, or alternate between deterministic, pseudo-random and random periods of operation. The scheduler/controller circuit 37 can be triggered in various ways, e.g. through the timer circuit 96 driven by the slave oscillator circuit 35 output signal 51, a threshold-crossing of the temperature compensator circuit 31, an external stimulus signal, etc.

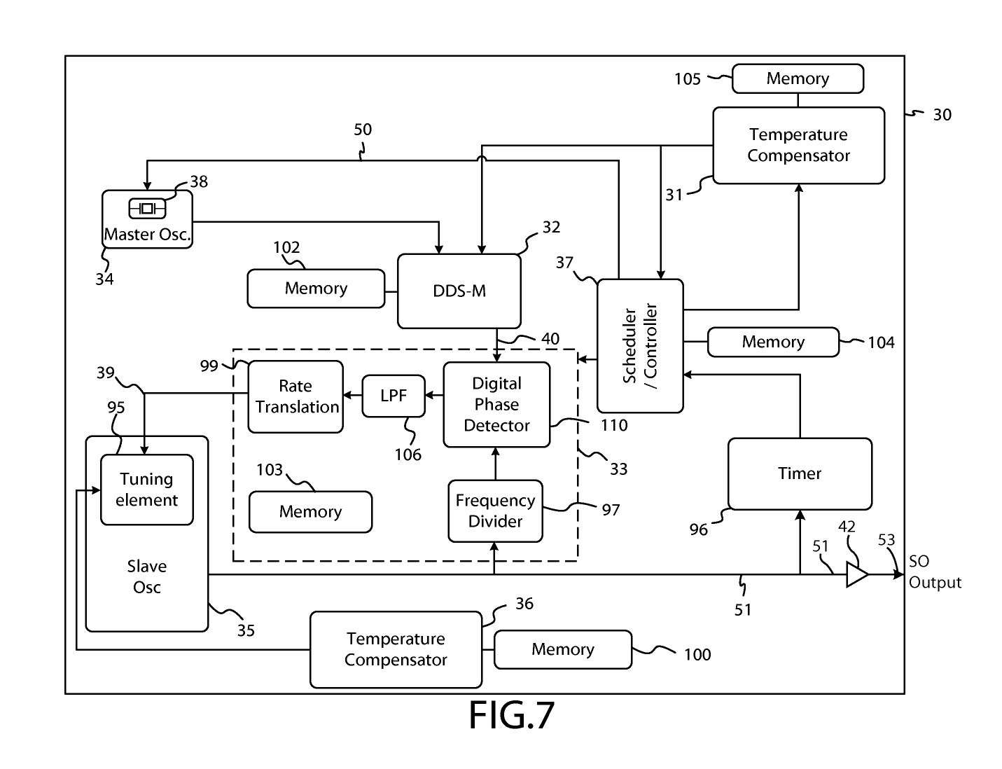

FIGS. 6 and 7 are related to the integrated reference frequency generator 30 shown in FIG. 3. The slave oscillator circuit 35 is adjusted directly through the tuning element 95. The frequency error is determined by the frequency adjustment circuit 33 and the frequency adjustment signal 39 is directly applied to the slave oscillator circuit 35 by adjusting the tuning element 95 in discrete steps (e.g. by selecting capacitor values from a bank) or in a continuous fashion (e.g. by varying a voltage across a varactor diode).

FIGS. 8 and 9 illustrate detailed functional block diagrams of embodiments of the integrated reference frequency generator 30 in accordance with aspects of this invention that are related to the arrangement in FIG. 4. In these embodiments, the frequency of the output 53 of the integrated frequency reference generator 30 is controlled through the adjustment of the divisor of the DDS-S circuit 45. The frequency error is determined by the frequency adjustment circuit 33 and the frequency adjustment signal 39 is applied to the divisor input of the DDS-S circuit 45.

The frequency of the slave oscillator output signal 51 may be temperature compensated in multiple ways. In one embodiment, the temperature compensator circuit 36 directly applies a frequency adjustment signal to a tuning element 95 of the slave oscillator circuit 35. In the embodiments shown in FIGS. 8 and 9, the temperature compensator circuit 36 applies a frequency adjustment signal to the DDS-S circuit 45. Either or both of the above embodiments can be implemented to enhance the temperature stability of the slave oscillator circuit 35.

The DDS-S circuit 45 in the embodiment presented in FIGS. 8 and 9 offers the additional capability of further adjusting the frequency of the output signal 53 of the integrated reference frequency generator 30 using, for example, a frequency modulation circuit 109. The frequency modulation circuit 109 can modulate the frequency of the output signal 53 using spread spectrum techniques to reduce the electromagnetic interference (EMI) or radio-frequency interference (RFI) generated by the integrated reference frequency generator 30 and/or by systems clocked by the output signal 53 of the integrated reference frequency generator 30. The DDS-S circuit 45 can implement all spread spectrum clock generation (SSCG) techniques, including common modulation patterns and schemes, modulation with very large spread (or deviation or modulation index), up spread, down spread, so-called Hershey Kiss modulation, fast modulation, slow modulation, etc. Modulation can be deterministic, pseudo-random or random.

In addition, the frequency modulation circuit 109 can alter the output signal 53 using dithering and related techniques, for example, to suppress spurious tones that may otherwise be generated by the DDS-S circuit 45. Dithering techniques include continuous-time and discrete-time modulation by a random or a pseudo-random signal, temporally shifting the edges of clock signals with random or pseudo-random jitter, etc.

Further, the frequency modulation circuit 109 can adjust the output signal 53 to correct deterministic errors that affect output signal 53. For example, the frequency modulation circuit 109 can measure the value of the power supply voltage applied to the integrated reference frequency generator 30 (or applied to some of its components), and it can adjust the output signal 53 to cancel frequency errors induced by variations of the supply voltage, based on a model or describing function of the sensitivity of the frequency of the output signal 53 to supply voltage variations.

An additional distinction in the embodiments of FIGS. 6-9 is in the implementation of the frequency adjustment circuit that determines the frequency adjustment signal 39 that is either directly applied to the slave oscillator circuit 35 as shown in FIGS. 6 and 7, or indirectly adjusts the divisor of the DDS-S circuit 45 as shown in FIGS. 8 and 9. To facilitate intermittent operation, the frequency adjustment circuit 33 described above may utilize various memory elements which are indicated as a single memory circuit 103 in FIGS. 6-9. Various methods can be utilized to determine the frequency and/or phase error.

In the embodiment of FIG. 6, an analog phase detector circuit 98 is implemented to frequency-mix the master reference frequency signal 40 with the output signal 51 of the slave oscillator circuit 35 divided by a frequency divider circuit 97 of the frequency adjustment circuit 33. Alternate analog frequency or phase detector circuits can be used in addition to or in place of the analog phase detector circuit 98. Examples include switching phase detectors, four-quadrant multipliers, ring modulators, etc. The output of the analog phase detector circuit 98 is low-pass filtered by an analog filter circuit 106 with an output holding circuit. The output of the analog filter circuit 106 is applied to a rate translation circuit 99. The rate translation circuit 99 translates the frequency error determined by the analog phase detector circuit 98 into a signal appropriate for the tuning element 95 that directly changes the frequency of the slave oscillator circuit 35 output signal 51, as described above.

In the embodiments of FIGS. 7 and 8, the frequency adjustment circuit 33 employs a digital phase detector circuit 110 (or phase/frequency detector (PFD) circuit or a digital pulse-count-and-compare circuit) which compares the master reference frequency signal 40 with the output signal 51 of the slave oscillator circuit 35 divided by a frequency divider circuit 97 (in the embodiment of FIG. 7), or with the output signal 52 of the DDS-S circuit 45 divided by the frequency divider circuit 97 (in the embodiment of FIG. 8). Depending on the requirements, the implementation the digital phase detector output may include a current-mode charge pump output. The output of the digital phase detector circuit 110 is then low-pass filtered by the analog filter circuit 106. A holding function may be implemented either at the output of the digital phase detector circuit 110 or at the output of the analog filter circuit 106.

In the embodiment of FIG. 7, the output of the analog filter circuit 106 is applied to the rate translation circuit 99 which translates the frequency error determined by the phase detector circuit 110 into the frequency adjustment signal 39 appropriate for the tuning element 95 to directly change the slave oscillator frequency, as described above. In the embodiment of FIG. 8, the rate translation circuit 99 converts the frequency error into the frequency adjustment signal 39 applied to the DDS-S circuit 45 to change the frequency of the output signal 53 of integrated frequency reference generator 30.

In the embodiment of FIG. 9, the frequency adjustment circuit 33 employs a Time-to-Digital Converter (TDC) circuit 111 to compute the phase error between the master reference frequency signal 40 and the output signal 52 of the DDS-S circuit 45 divided by the frequency divider circuit 97. Depending on the requirements, the Time-to-Digital Converter circuit 111 may include a reference clock signal derived from the master oscillator circuit 34 output signal 50. The phase error can be further filtered by a discrete time low-pass filter circuit 112. The filtered error signal is converted by the rate translation circuit 99 to a fractional divisor value and applied to the DDS-S circuit 45 as the frequency adjustment signal 39.

In the embodiments described above, the rate translation circuit 99 may implement linear translation, or alternate linear or nonlinear functions, that facilitate the adjustment and control of the output frequency of the integrated reference frequency generator 30. Optionally, for a higher comparison rate, the frequency divider circuit 97 may be bypassed.

Referring to FIG. 10, the output signal 51 of the slave oscillator circuit 35 may be further optionally divided by a frequency divider circuit 41 and buffered by buffer circuit 42 to drive external circuits as output signal 53 (SO output). In some embodiments, the master oscillator output signal 50 may be output as a separate reference signal from the DDS-M circuit 32 and may be optionally frequency-divided by a frequency divider circuit 43. The output of the frequency divider circuit 43 may be buffered by a separate buffer circuit 44 as the output signal 54 (MO Output), provided that the master oscillator circuit 34 operates continuously. Thus, the two independent oscillator outputs (MO Output, SO Output) may be obtained with the use of one master oscillator circuit 34 and one slave oscillator circuit 35 whose frequency is periodically adjusted.

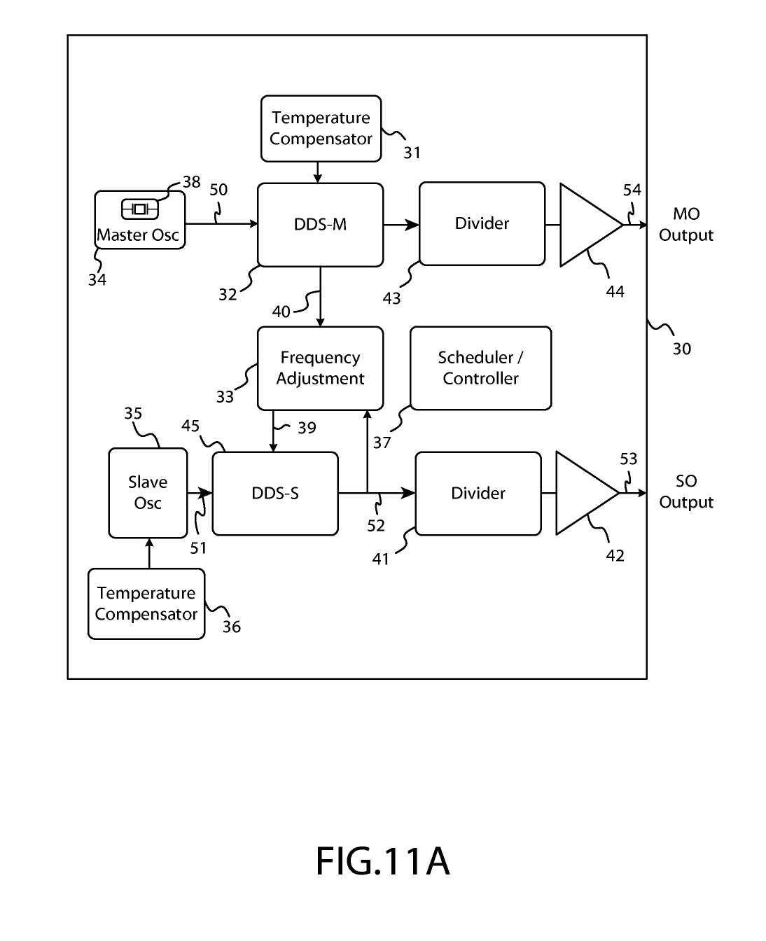

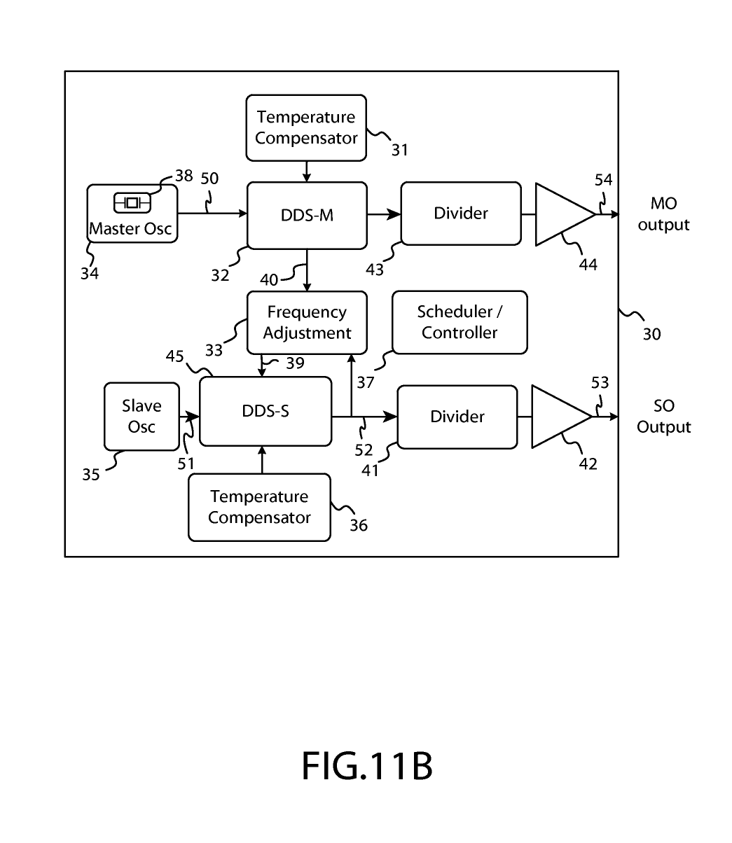

The configuration of the integrated reference frequency generator 30 of FIG. 4 may be further modified as illustrated in FIG. 11A. The integrated reference frequency generator 30 includes the frequency divider circuit 41 and the buffer circuit connected to the output of the DDS-S circuit 45. The integrated reference frequency generator 30 also includes the frequency divider circuit 43 and the buffer circuit 44 connected to the output of the DDS-M circuit 32. As described with reference to FIG. 10, the master oscillator output signal 50 is processed by the DDS-M circuit 32. The DDS-M circuit 32 provides the processed signal to the frequency adjustment circuit 33 as well as to the frequency divider circuit 43 and the buffer circuit 44. The frequency divider circuit 43 and the buffer circuit 44 make the master oscillator reference signal available as the output signal 54 (MO output), provided that the master oscillator circuit 34 operates continuously. The slave oscillator output signal 51 is processed by the DDS-S circuit 45 whose divisor is changed by the frequency adjustment circuit 33 according to the determined frequency error. The output signal 52 of the DDS-S circuit 45 may also be frequency divided by the frequency divider circuit 41 before it becomes available as the output signal 53 (SO output) via the buffer circuit 42. Thus, two independent oscillator output signals (MO Output 54, SO Output 53) can be obtained with the use of one master oscillator and one slave oscillator whose frequency is periodically adjusted.

FIG. 11B shows the functional block diagram of another embodiment in accordance with aspects of the invention. The difference between this embodiment and the embodiment of FIG. 11A is that the temperature compensator circuit 36 applies a digital signal to the DDS-S circuit 45.

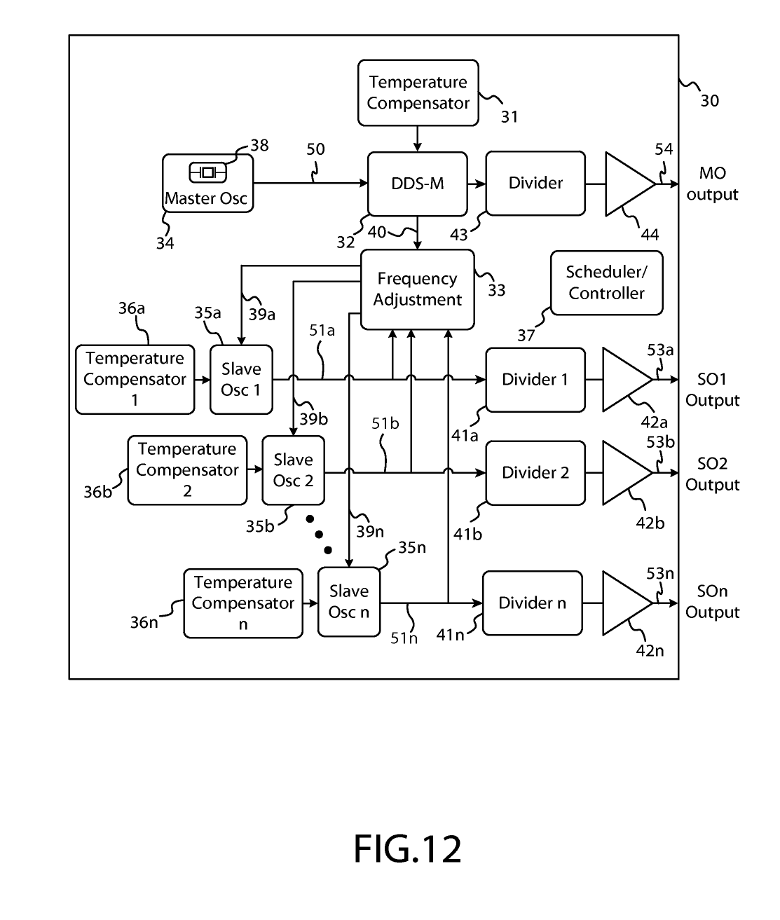

FIG. 12 illustrates a functional block diagram of another embodiment in accordance with aspects of the invention. The integrated reference frequency generator 30 is similar to the integrated reference frequency generator 30 described with reference to FIG. 10 with the addition of multiple slave oscillator circuits 35a, 35b, 35n, multiple temperature compensator circuits 36a, 36b, 36n, multiple frequency divider circuits 41a, 41b, 41n, and multiple buffer circuits 42a, 42b, 42n. In this case, the frequency of each output 53a, 53b, 53n (SO1 Output, SO2 Output, SOn Output) is individually adjusted by the frequency adjustment circuit 33 based on the master reference frequency signal 40 generated by the DDS-M circuit 32.

The master oscillator circuit 34 comprises the integrated BAW resonator 38 and drives the DDS-M circuit 32 which in turn outputs the master reference frequency signal 40 that is input to the frequency adjustment circuit 33. This reference frequency chain is controlled by the scheduler/controller circuit 37 which ensures that each of the slave oscillator circuits 35a, 35b, 35n is adjusted at the appropriate time interval. The frequency adjustment process is the same as described in the embodiment of FIG. 3 and happens by directly adjusting the frequency determining elements of the slave oscillator circuits 35a, 35b, 35n.

The temperature-dependent frequency drift of the master oscillator circuit 34 output signal 50 can be adjusted indirectly by the temperature compensator circuit 31 that periodically adjusts the divisor of the DDS-M circuit 32. The temperature-dependent frequency drift of the slave oscillator circuits 35a, 35b, 35n output signals 51a, 51b, 51n can be compensated through direct frequency adjustment by the temperature compensator circuits 36a, 36b, 36n. The advantage of having multiple slave oscillator circuits 35a, 35b, 35n is that a number of unrelated output frequencies can be generated with low power consumption, high frequency stability characteristics and a completely integrated reference frequency source.

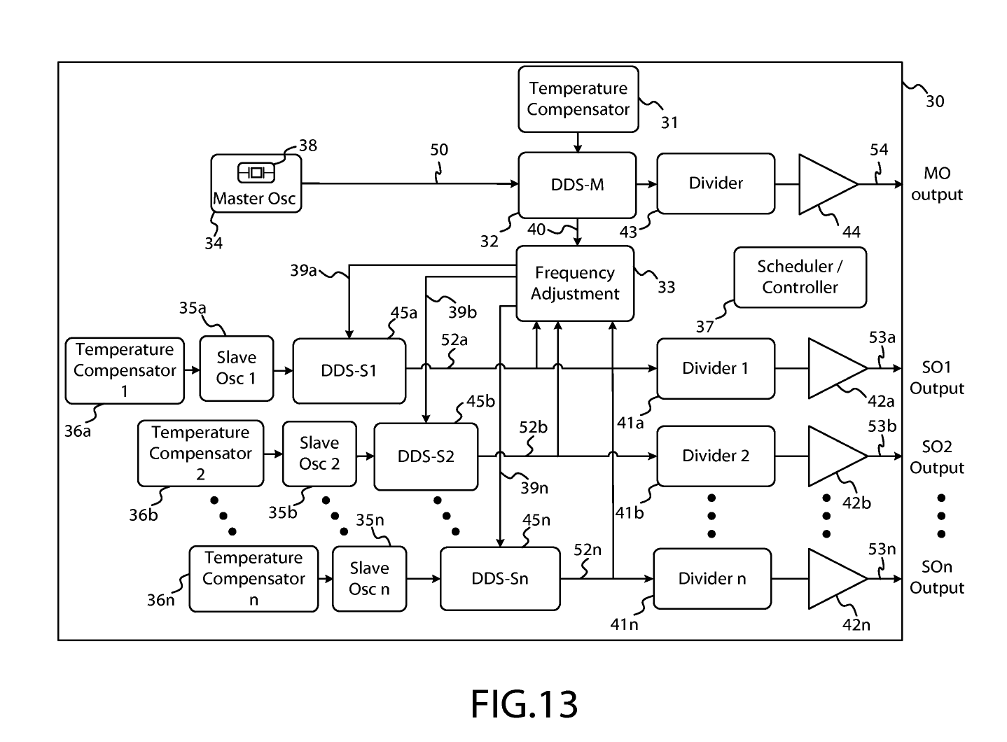

FIG. 13 illustrates a functional block diagram of another embodiment in accordance with aspects of the invention. The integrated reference frequency generator 30 of FIG. 13 is similar to the integrated reference frequency generator 30 described with reference to FIG. 12 with the addition of a DDS-S circuit 45a, 45b, 45n in each slave oscillator chain. The frequency of each slave oscillator chain is individually adjusted by the frequency adjustment circuit 33. The overall frequency adjustment approach is similar to the embodiment illustrated on FIG. 11A. The frequency adjustment circuit 33 compares the master reference frequency signal 40 to the output 51a, 51b, 51n of each DDS-S circuit 45a, 45b, 45n, separately. The frequency adjustment circuit 33 determines a frequency adjustment signal 39a, 39b, 39n for each slave oscillator circuit that is in turn applied to the corresponding DDS-S circuit 45a, 45b, 45n. The main difference between this embodiment and the embodiment illustrated on FIG. 12 is that the output frequency adjustment is accomplished by altering the divisors of the DDS-S circuits 45a, 45b, 45n cascaded with the slave oscillator circuits 35a, 35b, 35n. The scheduler/controller circuit 37 determines the updating of each slave oscillator path according to system requirements.

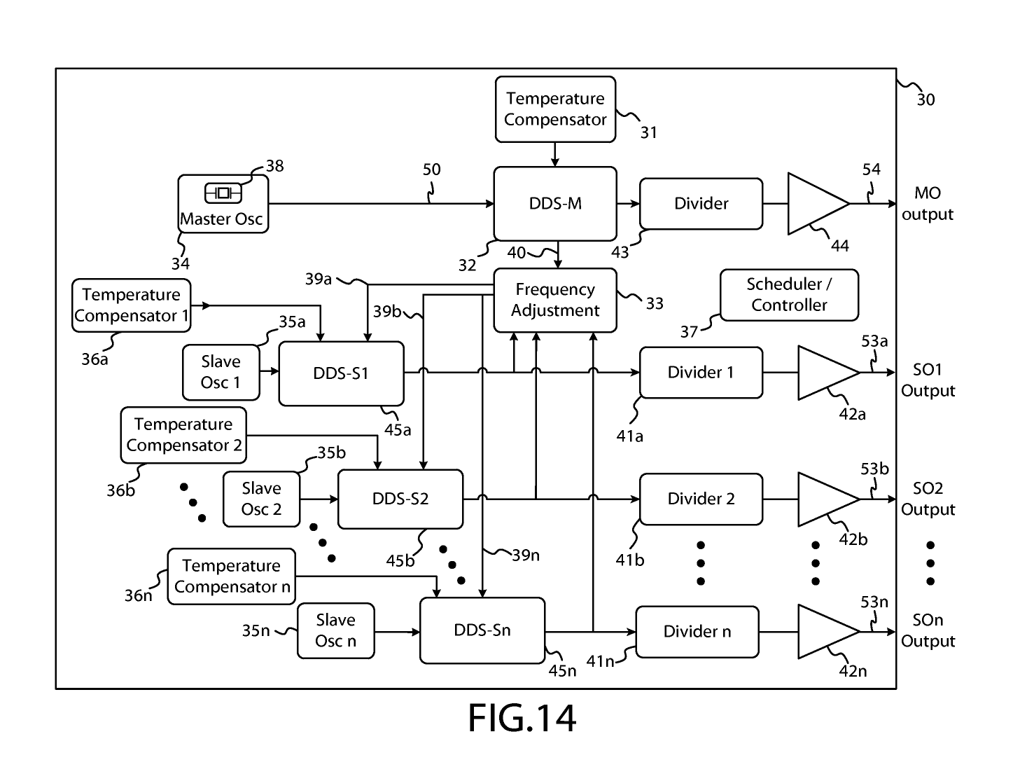

FIG. 14 illustrates a functional block diagram of another embodiment in accordance with aspects of the invention. The integrated reference frequency generator 30 of FIG. 14 is similar to the integrated reference frequency generator 30 described with reference to FIG. 13 with the temperature compensator circuits 36a, 36b, 36n in communication with the DDS-S circuits 45a, 45b, 45n instead of the slave oscillator circuits 35a, 35b, 35n.

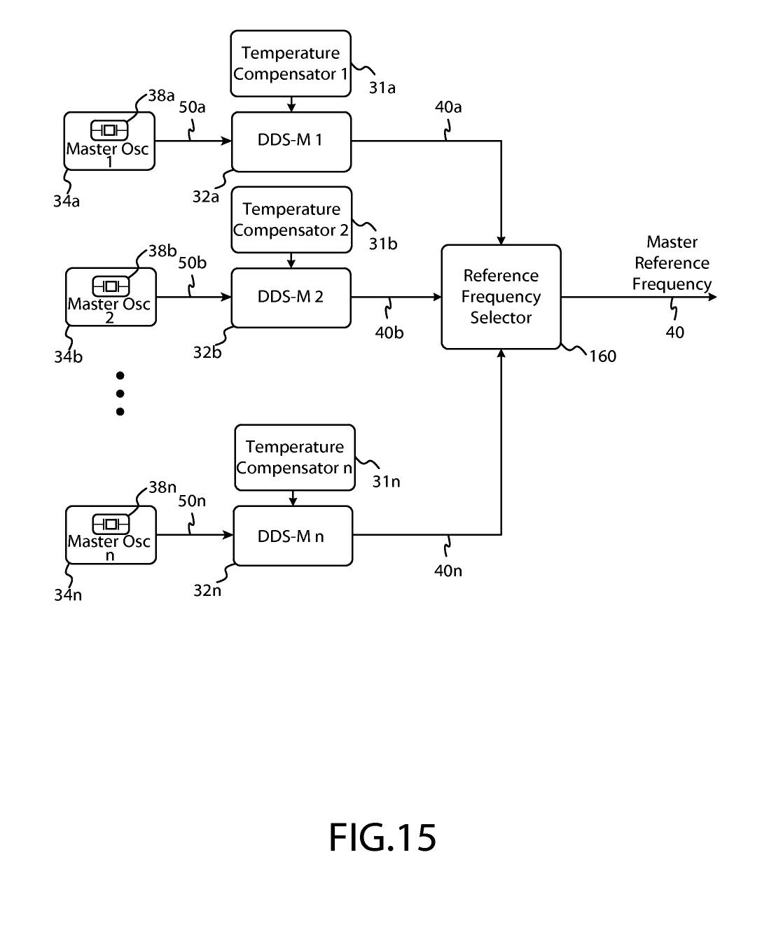

FIG. 15 illustrates a functional block diagram of another embodiment in accordance with aspects of the invention. This embodiment incorporates a number of master oscillator circuits 34a, 34b, 34n, each comprising an integrated BAW resonator 38a, 38b, 38n. Each master oscillator circuit 34a, 34b, 34n outputs a master oscillator output signal 50a, 50b, 50n that is processed by the corresponding DDS-M circuit 32a, 32b, 32n. Each DDS-M circuit 32a, 32b, 32n outputs an intermediate master reference frequency signal 40a, 40b, 40n. Each DDS-M circuit 32a, 32b, 32n is connected to a dedicated temperature compensator circuit 31a, 31b, 31n that adjusts the divisor of the DDS-M circuit 32a, 32b, 32n to compensate for temperature-induced frequency drift.

The intermediate master reference frequency signals 40a, 40b, 40n are processed by a reference frequency selector 160 to generate the master reference frequency signal 40. For example, the reference frequency selector 160 may compare all intermediate master reference frequency signals 40a, 40b, 40n against each other to determine which intermediate master reference frequency has drifted the least, e.g. due to aging or other reasons. Once this is determined, the selected intermediate master reference signal is used as the master reference frequency signal 40 and output to the slave oscillator adjustment circuit, as described above.

The circuit architecture described with reference to FIG. 15 introduces redundancy which greatly increases reliability of the master oscillator at the cost of limited increase in die area. If BAW resonator aging is the dominant issue to be addressed by redundancy, the circuit architecture illustrated in FIG. 15 can be further simplified, for example, by sharing a single temperature compensator circuit to control all of the DDS-M circuits 32a, 32b, 32n, or by sharing a single DDS-M circuit 32 to process all of the master oscillator output signals.

In an alternate embodiment related to the one illustrated on FIG. 15, an external reference signal source providing a high frequency stability signal can be used instead of one of master oscillator circuits 34a, 34b, 34n or in addition to them. This external reference signal can be used by reference frequency selector 160 to select the optimal master oscillator circuit 34a, 34b, 34n to generate the master reference frequency signal 40. Alternately, the external reference signal can be used to adjust the divisor of DDS circuits 32a, 32b, 32n to enhance the accuracy of master reference frequency signal 40. Reference frequency selector 160 may use techniques similar to the ones described for frequency adjustment circuit 33.

As these and other variations and combinations of the features described above can be utilized, the foregoing description of the preferred embodiments should be taken as illustrating, rather than limiting, the scope of the invention.

1. An integrated circuit device for generating an output signal, comprising:
an integrated circuit substrate;
a master oscillator circuit formed over the integrated circuit substrate, wherein a reference frequency signal is generated from the master oscillator circuit; and
a slave oscillator circuit formed over the integrated circuit substrate, wherein the output signal of the integrated circuit device is generated from the slave oscillator circuit,
wherein the master oscillator circuit is intermittently enabled,
wherein a frequency of the output signal of the integrated circuit device is intermittently adjusted with respect to a frequency of the reference frequency signal, and
wherein the master oscillator circuit comprises a bulk acoustic wave resonator.

2. The integrated circuit device of claim 1 further comprising an adjustment circuit for adjusting a frequency of the output signal of the integrated circuit device with respect to the frequency of the reference frequency signal.

3. The integrated circuit device of claim 2 further comprising a direct digital synthesizer circuit that is clocked by an output signal of the master oscillator circuit, wherein the reference frequency signal is generated by an output from the direct digital synthesizer circuit.

4. The integrated circuit device of claim 2 further comprising a fractional frequency divider circuit that is clocked by an output signal of the master oscillator circuit, wherein the reference frequency signal is generated by an output from the fractional frequency divider circuit.

5. The integrated circuit device of claim 2 wherein the output signal of the integrated circuit device is an output signal of the slave oscillator circuit divided by a frequency divider circuit and buffered by a buffer circuit, and wherein the adjustment circuit adjusts the frequency of the output signal of the integrated circuit device by adjusting the slave oscillator circuit.

6. The integrated circuit device of claim 2 further comprising a fractional frequency divider circuit that is clocked by an output signal of the slave oscillator circuit, wherein the output signal of the integrated circuit device is an output signal of the fractional frequency divider circuit buffered by a buffer circuit, and wherein the adjustment circuit adjusts the frequency of the output signal of the integrated circuit device by adjusting the fractional frequency divider circuit.

7. The integrated circuit device of claim 2 further comprising a direct digital synthesizer circuit that is clocked by an output signal of the slave oscillator circuit, wherein the output signal of the integrated circuit device is an output signal of the direct digital synthesizer circuit buffered by a buffer circuit, and wherein the adjustment circuit adjusts the frequency of the output signal of the integrated circuit device by adjusting the direct digital synthesizer circuit.

8. The integrated circuit device of claim 2 wherein the adjustment circuit comprises an analog phase detector circuit, an analog low-pass filter circuit, a holding circuit, and a rate translation circuit.

9. The integrated circuit device of claim 2 wherein the adjustment circuit comprises an analog frequency detector circuit, an analog low-pass filter circuit, a holding circuit, and a rate translation circuit.

10. The integrated circuit device of claim 2 wherein the adjustment circuit comprises a digital phase-frequency detection circuit, an analog low-pass filter circuit, a holding circuit, and a rate translation circuit.

11. The integrated circuit device of claim 2 wherein the adjustment circuit comprises a time-to-digital converter circuit, a digital discrete-time low-pass filter circuit, a holding circuit, and a rate translation circuit.

12. The integrated circuit device of claim 2 further comprising a plurality of slave oscillator circuits, wherein the output signal of the integrated circuit device comprises a plurality of output signals of the integrated circuit device, each slave oscillator circuit generating a slave oscillator circuit output signal comprising one of the plurality of output signals of the integrated circuit device.

13. The integrated circuit device of claim 12 wherein a frequency of each of the plurality of output signals of the integrated circuit device is adjusted with respect to the frequency of the reference frequency signal.

14. The integrated circuit device of claim 13 wherein each of the plurality of output signals of the integrated circuit device is the output signal of the corresponding slave oscillator circuit divided by a frequency divider circuit and buffered by a buffer circuit, and wherein the adjustment circuit adjusts the frequency of each of the plurality of output signals of the integrated circuit device by adjusting the corresponding slave oscillator circuit.

15. The integrated circuit device of claim 13 further comprising a plurality of fractional frequency divider circuits, each being clocked by the output signal of the corresponding slave oscillator circuit,
wherein each of the plurality of output signals of the integrated circuit device is the output signal of the corresponding fractional frequency divider circuit buffered by a buffer circuit, and
wherein the adjustment circuit adjusts the frequency of each of the plurality of output signals of the integrated circuit device by adjusting the corresponding fractional frequency divider circuit.

16. The integrated circuit device of claim 13 further comprising a plurality of direct digital synthesizer circuits, each being clocked by the output signal of the corresponding slave oscillator circuit,
wherein each of the plurality of output signals of the integrated circuit device is the output signal of the corresponding direct digital synthesizer circuit buffered by a buffer circuit, and
wherein the adjustment circuit adjusts the frequency of each of the plurality of output signals of the integrated circuit device by adjusting the corresponding direct digital synthesizer circuit.

17. The integrated circuit device of claim 1 wherein the frequency of the output signal of the integrated circuit device is lower than the frequency of the reference frequency signal, wherein the frequency of the reference frequency signal is in a range of 500 MHz to 5 GHz.

18. The integrated circuit device of claim 1 wherein the output signal of the integrated circuit device is a real time clock signal.

19. The integrated circuit device of claim 1 wherein the bulk acoustic wave resonator comprises a piezoelectric material.

20. The integrated circuit device of claim 1 further comprising a circuit to modulate a frequency of the output signal of the integrated circuit device using spread spectrum techniques.

21. The integrated circuit device of claim 1 further comprising a circuit to dither the output signal of the integrated circuit device.

22. The integrated circuit device of claim 1 further comprising a circuit for adjusting a frequency of the output signal of the integrated circuit device to correct an error.

23. The integrated circuit device of claim 1 further comprising a circuit for enabling and disabling the master oscillator circuit.

24. The integrated circuit device of claim 1 further comprising a frequency divider circuit and a buffer circuit, wherein the frequency divider circuit and the buffer circuit generate a second output signal from the master oscillator circuit when the master oscillator circuit is enabled.

25. The integrated circuit device of claim 1 wherein the integrated circuit device is packaged in a single integrated circuit package.

26. The integrated circuit device of claim 25 wherein the integrated circuit device is packaged using chip scale packaging.

27. The integrated circuit device of claim 1 further comprising a temperature drift compensator circuit.

28. The integrated circuit device of claim 1 wherein:
the master oscillator circuit comprises a plurality of intermediate master oscillator circuits, wherein each intermediate master oscillator circuit comprises a bulk acoustic wave resonator;
the integrated circuit device further comprising a plurality of direct digital synthesizer circuits, each being coupled to a corresponding intermediate master oscillator circuit, wherein each direct digital synthesizer circuit receives as input an output signal of the corresponding intermediate master oscillator circuit, each direct digital synthesizer circuit outputting an intermediate master reference frequency signal; and
the integrated circuit device further comprises a reference frequency selector circuit for receiving as inputs the intermediate master reference frequency signals, wherein the reference frequency selector circuit selects one of the intermediate master reference frequency signals to output as a master reference signal.

29. The integrated circuit device of claim 28 wherein the reference frequency selector circuit selects the intermediate master reference frequency signal that has drifted the least relative to the other intermediate master reference frequency signals.

30. The integrated circuit device of claim 28 wherein a reference signal provided from an external source is used by the reference frequency selector circuit to select the master reference signal.

31. An integrated circuit device for generating an output signal, comprising:
means for generating a reference frequency signal from a master oscillator circuit;
means for generating an output signal of the integrated circuit device from a slave oscillator circuit;
means for intermittently enabling the master oscillator circuit; and
means for intermittently adjusting a frequency of the output signal of the integrated circuit device with respect to a frequency of the reference frequency signal.
